(19) United States
(12) Patent Application Publication
(10) Pub. No.: US 2026/0221200 A1
(43) Pub. Date: Jul. 30, 2026

(54) SEMICONDUCTOR MEMORY DEVICE

(71) Applicant: Kioxia Corporation, Tokyo (JP)

(72) Inventors: Fumitaka ARAI, Yokkaichi Mie (JP); Shunichi SENO, Yokkaichi Mie (JP); Tatsuo OGURA, Yokkaichi Mie (JP)

(73) Assignee: Kioxia Corporation, Tokyo (JP)

(21) Appl. No.: 19/321,232

(22) Filed: Sep. 7, 2025

(30) Foreign Application Priority Data
Jan. 24, 2025 (JP) 2025-010721

(51) Int. Cl. G11C 16/26; G11C 5/06; G11C 16/04; G11C 16/08; G11C 16/32; G11C 16/34

(52) U.S. Cl. CPC G11C 16/26; G11C 5/063; G11C 16/0483; G11C 16/08; G11C 16/32; G11C 16/3436

(57) ABSTRACT

According to one embodiment, a semiconductor memory device includes a plurality of memory strings stacked apart from each other in a first direction and each including a plurality of memory cells which are arranged side by side in a second direction and whose current paths are coupled in series, a word line coupled to gates of a plurality of first memory cells stacked apart from each other in the first direction, a plurality of bit lines. Each of the memory cells is capable of storing data corresponding to one of a plurality of states. In the program operation, the states are classified into a plurality of groups, and a row decoder applies to the word line a plurality of pulse voltages respectively corresponding to the groups. In the program verify operation, the row decoder applies to the word line a plurality of verify voltages respectively corresponding to the states.

### CROSS-REFERENCE TO RELATED APPLICATION(S)

This application is based upon and claims the benefit of priority from Japanese Patent Application No. 2025-010721, filed Jan. 24, 2025, the entire contents of which are incorporated herein by reference.

### FIELD

Embodiments described herein relate generally to a semiconductor memory device.

### BACKGROUND

A three-dimensional stacked NAND flash memory is known as a semiconductor memory device.

### BRIEF DESCRIPTION OF THE DRAWINGS

FIG. 1 is a block diagram showing the overall configuration of a semiconductor memory device according to a first embodiment.

FIG. 2 is a circuit diagram showing an example of a circuit configuration of a memory cell array included in the semiconductor memory device according to the first embodiment.

FIG. 3 is a perspective view three-dimensionally showing an example of the circuit configuration of the memory cell array included in the semiconductor memory device according to the first embodiment.

FIG. 4 is a plan view showing an example of the planar layout of the memory cell array included in the semiconductor memory device according to the first embodiment.

FIG. 5 is a cross-sectional view taken along line IV-IV of FIG. 4 and showing an example of a cross-sectional structure of the memory cell array included in the semiconductor memory device according to the first embodiment.

FIG. 6 is a cross-sectional view taken along line V-V of FIG. 5 and showing an example of the cross-sectional structure of a memory cell transistor included in the semiconductor memory device according to the first embodiment.

FIG. 7 is a cross-sectional view taken along line VI-VI of FIG. 4 and showing an example of the cross-sectional structure of the memory cell array included in the semiconductor memory device according to the first embodiment.

FIG. 8 is a cross-sectional view taken along line VII-VII of FIG. 7 and showing an example of the cross-sectional structure of a selection transistor included in the semiconductor memory device according to the first embodiment.

FIG. 9 is a diagram showing threshold voltage distributions and data allocation in a case where the memory cell transistor included in the semiconductor memory device according to the first embodiment is a TLC.

FIG. 10 is a diagram shows an example of a change in the threshold voltage distributions of the memory cell transistors that is performing a multi-pulse write operation.

FIG. 11 is a diagram showing an example of state grouping in a case where the memory cell transistor included in the semiconductor memory device according to the first embodiment is the TLC.

FIG. 12 is a timing chart showing an example of voltage of each interconnect in the multi-pulse write operation of the semiconductor memory device according to the first embodiment.

FIG. 13 is a flowchart showing an example of a flow of the multi-pulse write operation of the semiconductor memory device according to the first embodiment.

FIG. 14 is a diagram showing a modification to the state grouping in a case where the memory cell transistor included in the semiconductor memory device according to the first embodiment is the TLC.

FIG. 15 is a timing chart showing an example of voltages of a selected word line in a multi-pulse write operation of a semiconductor memory device according to a second embodiment.

FIG. 16 is a diagram showing an example of pulse voltage application conditions in the multi-pulse write operation of the semiconductor memory device according to the second embodiment.

FIG. 17 is a diagram showing a transition of the threshold voltage distributions for each group in the multi-pulse write operation of the semiconductor memory device according to the second embodiment.

FIG. 18 is a diagram showing an example of state grouping in a case where a memory cell transistor included in a semiconductor memory device according to a third embodiment is a TLC.

FIG. 19 is a timing chart showing an example of voltage of each interconnect in a multi-pulse write operation of the semiconductor memory device according to the third embodiment.

FIG. 20 is a diagram showing a transition of the threshold voltage distributions for each state in the multi-pulse write operation of the semiconductor memory device according to the third embodiment.

### DETAILED DESCRIPTION

In general, according to one embodiment, a semiconductor memory device includes a plurality of memory strings stacked apart from each other in a first direction and each including a plurality of memory cells which are arranged side by side in a second direction intersecting the first direction and whose current paths are coupled in series, a word line extending in the first direction and coupled to gates of a plurality of first memory cells which are among the plurality of memory cells and stacked apart from each other in the first direction, a plurality of bit lines respectively coupled to the plurality of memory strings, a row decoder coupled to the word line, a sense amplifier coupled to the plurality of bit lines, and a controller configured to perform a write operation by repeating a program loop including a program operation and a program verify operation. Each of the plurality of memory cells is capable of storing data corresponding to one of a plurality of states. In the program operation of the plurality of first memory cells, the plurality of states are classified into a plurality of groups, and the row decoder applies to the word line a plurality of pulse voltages respectively corresponding to the plurality of groups. In the program verify operation of the plurality of first memory cells, the row decoder applies to the word line a plurality of verify voltages respectively corresponding to the plurality of states.

Embodiments will be described below with reference to the drawings. In the following description, components having the same function and configuration are denoted by common reference symbols. In order to distinguish a plurality of components with common reference symbols, different suffixes are attached to the common reference symbols. Unless a plurality of components are particularly distinguished, only common reference symbols are attached to the components and no suffixes are attached thereto. The suffixes are not limited to subscripts or superscripts, but include a lowercase alphabet added to the end of a reference symbol, an index representing an array, and the like.

### 1. First Embodiment

A semiconductor memory device 1 according to a first embodiment will be described. The semiconductor memory device 1 is a NAND flash memory capable of storing data nonvolatilely. Note that the semiconductor memory device 1 is not limited to a NAND flash memory. The semiconductor memory device 1 may be any other nonvolatile memory.

### 1.1 Configuration

### 1.1.1 Overall Configuration of Semiconductor Memory Device

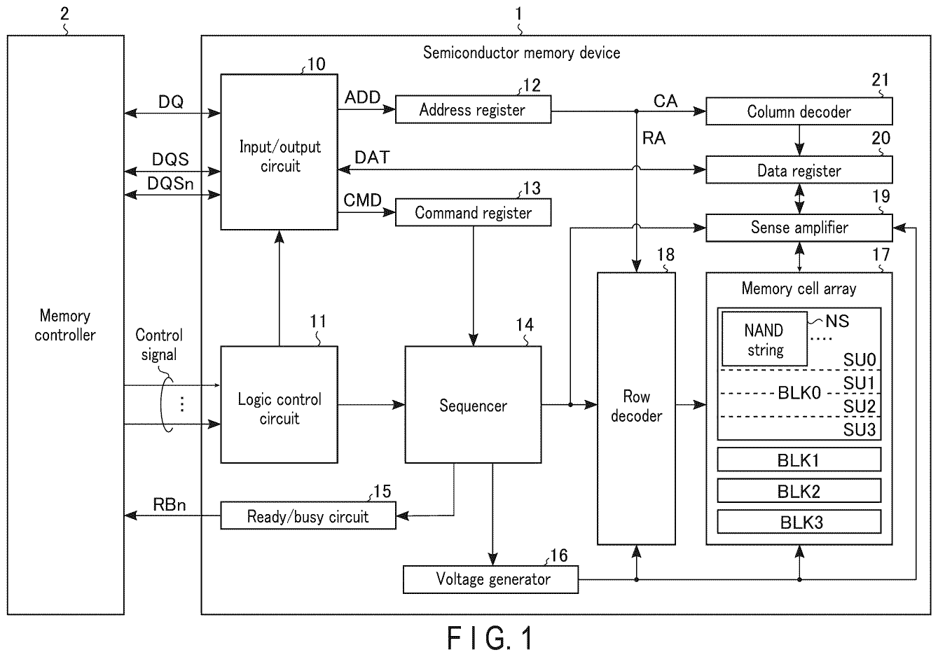

First, an example of the overall configuration of the semiconductor memory device 1 will be described with reference to FIG. 1. FIG. 1 is a block diagram showing the overall configuration of the semiconductor memory device 1. In FIG. 1, some of the couplings between components are indicated by arrows, but the couplings between the components are not limited to this.

As shown in FIG. 1, the semiconductor memory device 1 is configured to be controllable by an external memory controller 2. For example, the semiconductor memory device 1 transmits and receives a signal DQ and timing signals DQS and DQSn to and from the memory controller 2. The signal DQ is, for example, data DAT, an address ADD, or a command CMD. The timing signals DQS and DQSn are used when data DAT is input and output. The timing signal DQSn is an inverted signal of the timing signal DQS.

The semiconductor memory device 1 receives various control signals from the memory controller 2. Then, the semiconductor memory device 1 transmits a ready/busy signal RBn to the memory controller 2. The ready/busy signal RBn is a signal indicating whether the semiconductor memory device 1 cannot receive a command CMD from the memory controller 2 (it is in a busy state) or can receive it therefrom (it is in a ready state).

The semiconductor memory device 1 includes an input/output circuit 10, a logic control circuit 11, an address register 12, a command register 13, a sequencer 14, a ready/busy circuit 15, a voltage generator 16, a memory cell array 17, a row decoder 18, a sense amplifier 19, a data register 20, and a column decoder 21.

The input/output circuit 10 is a circuit to and from which a signal DQ is input and output. The input/output circuit 10 is coupled to the memory controller 2. The input/output circuit 10 is also coupled to the logic control circuit 11, address register 12, command register 13, and data register 20.

In a case where the input signal DQ is an address ADD, the input/output circuit 10 transmits the address ADD to the address register 12. In a case where the input signal DQ is a command CMD, the input/output circuit 10 transmits the command CMD to the command register 13. In a case where the input signal DQ is data DAT, the input/output circuit 10 receives the input signal DQ based on the timing signals DQS and DQSn. Then, the input/output circuit 10 transmits the data DAT to the data register 20. The input/output circuit 10 outputs the data DAT to the memory controller 2 together with the timing signals DQS and DQSn.

The logic control circuit 11 performs logic control based on the control signals. The logic control circuit 11 is coupled to the memory controller 2. The logic control circuit 11 is also coupled to the input/output circuit 10 and the sequencer 14. The logic control circuit 11 receives a plurality of control signals from the memory controller 2. The logic control circuit 11 controls the input/output circuit 10 and the sequencer 14 based on the received control signals.

The address register 12 temporarily stores the address ADD. The address register 12 is coupled to the input/output circuit 10, row decoder 18, and column decoder 21. The address ADD includes a row address RA and a column address CA. The row address RA is an address for selecting the interconnects (word lines and select gate lines) arranged in the row direction in the memory cell array 17. The column address CA is an address for selecting interconnects (bit lines) arranged in the column direction in the memory cell array 17. For example, the row address RA includes a block address and a page address. The block address is an address to designate one of a plurality of blocks BLK included in the memory cell array 17. The page address is an address to designate one of a plurality of word lines coupled to the blocks BLK. The address register 12 transfers the row address RA to the row decoder 18. The address register 12 also transfers the column address CA to the column decoder 21.

The command register 13 temporarily stores the command CMD. The command register 13 is coupled to the input/output circuit 10 and the sequencer 14. The command register 13 transfers the command CMD to the sequencer 14.

In some exemplary embodiments, the sequencer 14 is a circuit or a component that controls timing of operations of various components of the semiconductor memory device 1. In some exemplary embodiments, the sequencer 14 may operate as a control circuit or a controller. In some exemplary embodiments, the sequencer 14 is implemented as a logic circuit, ASIC, FPGA or any combination of them. In some exemplary embodiments, the sequencer 14 may apply various voltages, pulses or signals to various components of the semiconductor memory device 1 to control timing of operations of the components of the semiconductor memory device 1 as described herein.

The sequencer 14 is a controller that controls the semiconductor memory device 1. The sequencer 14 controls the entire operation of the semiconductor memory device 1. For example, the sequencer 14 controls the ready/busy circuit 15, voltage generator 16, row decoder 18, sense amplifier 19, data register 20, and column decoder 21. For example, the sequencer 14 performs a write operation, a read operation, an erase operation and the like based on the command CMD.

In addition, the sequencer 14 manages the grouping of write states of memory cell transistors MC to be described later.

The ready/busy circuit 15 transmits a ready/busy signal RBn to the memory controller 2 under the control of the sequencer 14.

The voltage generator 16 generates various voltages for use in the write operation, the read operation and the erase operation under the control of the sequencer 14. The voltage generator 16 applies the generated voltages to the memory cell array 17, row decoder 18, sense amplifier 19, and the like. For example, in the write operation, the voltage generator generates a plurality of pulse voltages having different voltage values and applies the generated pulse voltages to the row decoder 18.

The memory cell array 17 is a set of a plurality of memory cell transistors (also referred to simply as “memory cells”) arranged in three dimensions. The memory cell array 17 includes a plurality of blocks BLK. In the example shown in FIG. 1, memory cell array 17 includes four blocks BLK0, BLK1, BLK2, and BLK3. The blocks BLK are, for example, a set of a plurality of memory cell transistors whose data are collectively erased. That is, the block BLK is a data erase unit. Each of the blocks BLK includes a plurality of string units SU. In the example shown in FIG. 1, each of the blocks BLK includes four string units SU0 to SU3. Each of the string units SU includes a plurality of NAND strings NS. Note that the number of blocks BLK in the memory cell array 17 and the number of string units SU in each of the blocks BLK may be any number. Details of the configuration of the memory cell array 17 will be described later.

The row decoder 18 is a circuit for decoding the row address RA. The row decoder 18 selects one of the blocks BLK in the memory cell array 17 based on a result of the decoding. The row decoder 18 applies voltages to the interconnects (word lines and select gate lines) in the row direction of the selected block BLK.

The sense amplifier 19 is a circuit that writes and reads data DAT. The sense amplifier 19 is coupled to the memory cell array 17 and the data register 20. During the read operation, the sense amplifier 19 reads data DAT from the memory cell array 17 via interconnects (bit lines) in the column direction. During the write operation, the sense amplifier 19 supplies voltages based on the write data DAT and the threshold voltages of the memory cell transistors to the memory cell array 17.

The data register 20 temporarily stores the data DAT. The data register 20 is coupled to the sense amplifier 19 and the column decoder 21. The data register 20 includes a plurality of latch circuits. Each of the latch circuits temporarily stores write data or read data.

The column decoder 21 is a circuit that decodes the column address CA. The column decoder 21 receives the column address CA from the address register 12. The column decoder 21 selects the latch circuits in the data register 20 based on a result of the decoding of the column address CA.

### 1.1.2 Circuit Configuration of Memory Cell Array

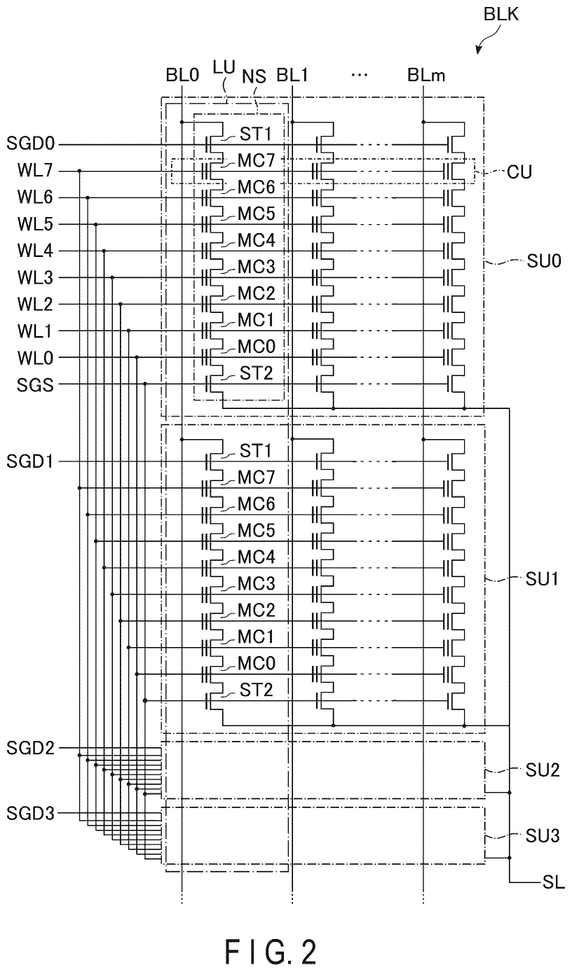

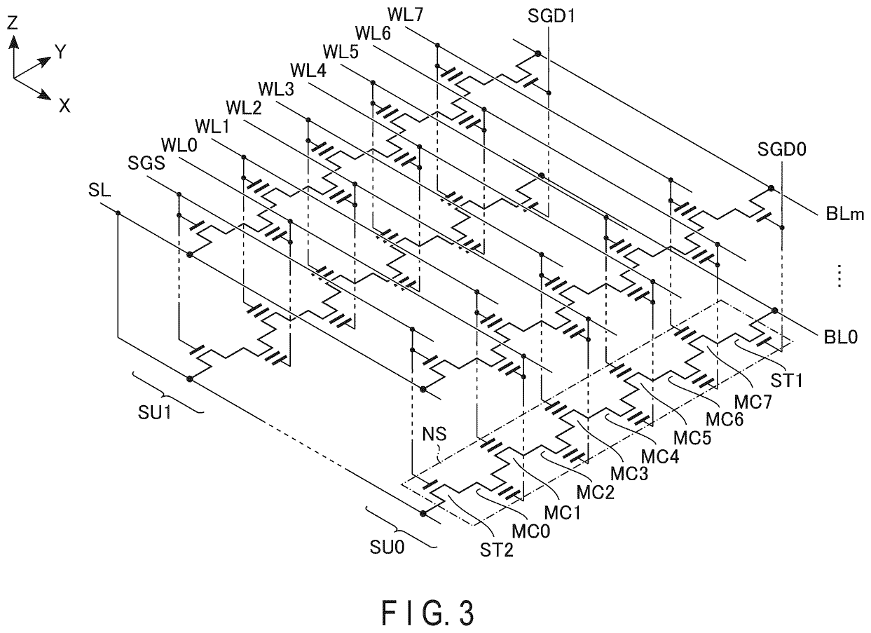

An example of the circuit configuration of the memory cell array 17 will be described below with reference to FIGS. 2 and 3. FIG. 2 is a circuit diagram showing an example of the circuit configuration of the memory cell array 17. FIG. 3 is a perspective view three-dimensionally showing an example of the circuit configuration of the memory cell array 17. Note that the example shown in FIG. 2 is directed to a circuit configuration of one block BLK. The example shown in FIG. 3 is directed to a circuit configuration of the string units SU0 and SU1.

In the first embodiment, the NAND strings NS in each string unit SU are stacked above the substrate. Hereinafter, the plane parallel to the surface of the substrate is defined as an XY plane. The directions crossing each other in the XY plane are defined as an X direction and a Y direction. The direction from the substrate toward the memory cell array 17 is defined as a Z direction. In the Z direction, the direction from the substrate toward the memory cell array 17 is defined as an upward direction, and the direction from the memory cell array 17 toward the substrate is defined as a downward direction.

As shown in FIG. 2, each string unit SU includes a plurality of NAND strings NS.

Each of the NAND strings NS includes a plurality of memory cell transistors MC and selection transistors ST1 and ST2. In the example shown in FIG. 2, each NAND string NS includes eight memory cell transistors MC0 to MC7. Note that the number of memory cell transistors MC included in each NAND string NS is arbitrary.

The memory cell transistors MC are memory elements that store data in a nonvolatile manner. The memory cell transistors MC each include a control gate and a charge storage film. The memory cell transistors MC may be metal-oxide-nitride-oxide-silicon (MONOS) type or a floating gate (FG) type. In the MONOS type transistors, an insulator is used for the charge storage film. In the FG type transistors, a conductor is used for the charge storage film. Below is a description of a case where the memory cell transistors MC are FG type transistors.

The selection transistors ST1 and ST2 are switching elements. The selection transistors ST1 and ST2 are each used to select a string unit SU in various operations. The number of selection transistors ST1 and ST2 included in each NAND string NS is arbitrary. One or more of the selection transistors ST1 and ST2 have only to be included in each NAND string NS.

The current paths of the selection transistor ST2, the memory cell transistors MC0 to MC7, and the selection transistor ST1 in each NAND string NS are coupled in series. The drain of the selection transistor ST1 is coupled to the bit line BL. The source of the selection transistor ST2 is coupled to the source line SL.

The control gates of the memory cell transistors MC0 to MC7 in the same block BLK are coupled to their respective word lines WL0 to WL7. More specifically, for example, the block BLK includes four string units SU0 to SU3. Each string unit SU includes a plurality of memory cell transistors MC0. The control gates of the memory cell transistors MC0 in the block BLK are coupled in common to one word line WL0. The same applies to the memory cell transistors MC1 to MC7.

The gates of the selection transistors ST1 in each string unit SU are coupled in common to one select gate line SGD. More specifically, the gates of the selection transistors ST1 in the string unit SU0 are coupled in common to the select gate line SGD0. The gates of the selection transistors ST1 in the string unit SU1 are coupled in common to the select gate line SGD1. The gates of the selection transistors ST1 in the string unit SU2 are coupled in common to the select gate line SGD2. The gates of the selection transistors ST1 in the string unit SU3 are coupled in common to the select gate line SGD3.

The gates of a plurality of selection transistors ST2 in the block BLK are coupled in common to the select gate line SGS. Similar to the select gate line SGD, a different select gate line SGS may be provided for each string unit SU.

The word lines WL0 to WL7, select gate lines SGD0 to SGD3 and select gate line SGS are each coupled to the row decoder 18.

The bit line BL is coupled in common to one NAND string NS in each string unit SU of each block BLK. A set of NAND strings NS coupled to one bit line BL is also referred to as a layer unit LU. For example, a plurality of NAND strings NS in the layer unit LU are arranged in the same layer. The same column address CA is assigned to the NAND strings NS coupled to one bit line BL. Each bit line BL is coupled to the sense amplifier 19.

The source line SL is shared among a plurality of blocks BLK, for example.

A set of memory cell transistors MC coupled to a common word line WL in one string unit SU is referred to as, for example, “cell unit CU”. The write operation and read operation are executed for each cell unit CU. A page is a unit of data collectively written to (or collectively read from) the cell unit CU. For example, when the memory cell transistor MC stores one-bit data, the storage capacity of the cell unit CU is one page. That is, the cell unit CU stores one-page data. The cell unit CU may have a storage capacity of two or more pages based on the number of bits of data stored in the memory cell transistor MC. The memory cell transistor MC may be a single level cell (SLC) that stores 1-bit data or a multi level cell (MLC) that stores 2-bit data. The memory cell transistor MC may also be a triple level cell (TLC) that stores 3-bit data, a quad level cell (QLC) that stores 4-bit data or a penta level cell (PLC) that stores 5-bit data. Below is a description of a case where the memory cell transistor MC in the first embodiment is a TLC.

As shown in FIG. 3, the NAND strings NS of each string unit SU are stacked apart from each other in the Z direction. The memory cell transistors MC0 to MC7 and the selection transistors ST1 and ST2 in each NAND string NS are arranged on the XY plane. The gates of the memory cell transistors MC stacked apart from each other in the Z direction in each string unit SU are coupled in common to one word line WL extending in the Z direction. More specifically, for example, in the string unit SU0, the gates of the memory cell transistors MC0 stacked apart from each other in the Z direction are coupled in common to the word line WL0. The same applies to the gates of the memory cell transistors MC1 to MC7.

The memory cell transistors MC included in the cell unit CU are spaced apart from each other in the Z direction. Therefore, in the write operation and the read operation, the memory cell transistors MC arranged apart from each other in the Z direction in each string unit SU are selected collectively.

The drains of the selection transistors ST1 in each string unit SU are coupled to different bit lines BL. For example, the bit lines BL are stacked apart from each other in the Z direction. The drains of the selection transistors ST1 provided in the same layer of each string unit SU are coupled in common to one bit line BL. More specifically, for example, the drain of the selection transistor ST1 corresponding to the NAND string NS located on the lowermost layer of each string unit SU is coupled to the bit line BL0. The drain of the selection transistor ST1 corresponding to the NAND string NS located on the m-th (m is an integer of one or more) layer of each string unit SU is coupled to the bit line BLm.

### 1.1.3 Configuration of Memory Cell Array

Next is a description of an example of the configuration of the memory cell array 17.

### 1.1.3.1 Planar Layout

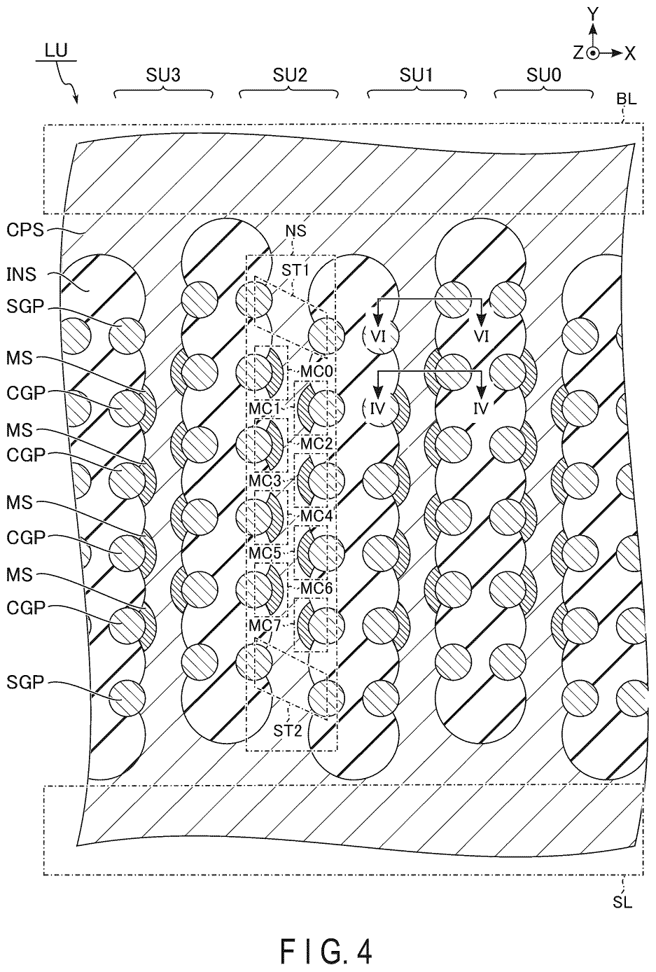

First, an example of a planar layout of the memory cell array 17 will be described with reference to FIG. 4. FIG. 4 is a plan view showing an example of the planar layout of the memory cell array 17. In FIG. 4, the plan view of a layer of the block BLK having substantially the same height (i.e., the position in the Z direction) from the substrate is shown. The portion shown in FIG. 4 corresponds to one layer unit LU in the circuit diagram shown in FIG. 2.

As shown in FIG. 4, in the same layer, the memory cell array 17 includes a plurality of conductive pillars CGP and SGP, a plurality of memory structures MS, a plurality of insulators INS, and a semiconductor CPS.

The insulators INS extend in the Y direction. The insulators INS each include, for example, a silicon oxide. In the example shown in FIG. 4, five insulators INS are arranged apart from each other in the X direction.

The semiconductor CPS expands in the XY plane. The semiconductor CPS includes, for example, polysilicon. The semiconductor CPS has a linear portion located between two insulators INS adjacent in the X direction and extending in the Y direction. In addition, the semiconductor CPS has both end portions between which the five insulators INS are sandwiched in the Y direction. The both end portions of the semiconductor CPS are coupled via the linear portion.

Each of the conductive pillars CGP and SGP extends in the Z direction so as to intersect the insulators INS and semiconductor CPS. Each of the conductive pillars CGP and SGP is provided at a boundary between each of the insulators INS and the semiconductor CPS in a region where two adjacent insulators INS are opposed to each other. That is, each of the conductive pillars CGP and SGP has a side surface opposed to the semiconductor CPS without interposing the insulator INS therebetween and a side surface opposed to the insulators INS without interposing the semiconductor CPS in planar view viewed from the Z direction. The conductive pillars CGP and SGP are arranged in the Y direction at the boundaries between the insulators INS and the linear portion of the semiconductor CPS. In the example shown in FIG. 4, four conductive pillars CGP are arranged so as to be sandwiched between two conductive pillars SGP in the Y direction. A portion where each of the conductive pillars CGP and SGP is opposed to the semiconductor CPS functions as a transistor.

A memory structure MS is provided between the semiconductor CPS and each of the conductive pillars CGP and includes a charge storage film. The memory structure MS is not provided between its corresponding insulator INS and conductive pillar CGP. For example, the memory structure MS has a sector shape in planar view viewed from the Z direction. A portion where each of the conductive pillars CGP is in contact with the semiconductor CPS with the corresponding memory structure MS therebetween functions as a memory cell transistor MC. Note that the memory structure MS is not provided between the semiconductor CPS and the conductive pillar SGP. Thus, a portion where each of the conductive pillars SGP is in contact with the semiconductor CPS does not function as a memory cell transistor MC but functions as a selection transistor ST1 or ST2. Eight sets of conductive pillars CGP and memory structure MS and four conductive pillars SGP, which are provided at a boundary between one linear portion of the semiconductor CPS and an insulator INS provided at one end of the linear portion and a boundary between the linear portion and an insulator INS provided at the other end of the linear portion, function as one NAND string NS. In FIG. 4, four NAND strings NS including five insulators INS and semiconductor CPS correspond to their respective string units SU0 to SU3.

The linear portion of the semiconductor CPS functions as a channel of each NAND string NS. One end of the semiconductor CPS functions as a bit line BL. The other end of the semiconductor CPS functions as a source line SL.

### 1.1.3.2 Cross-Sectional Structure of Conductive Pillar CGP

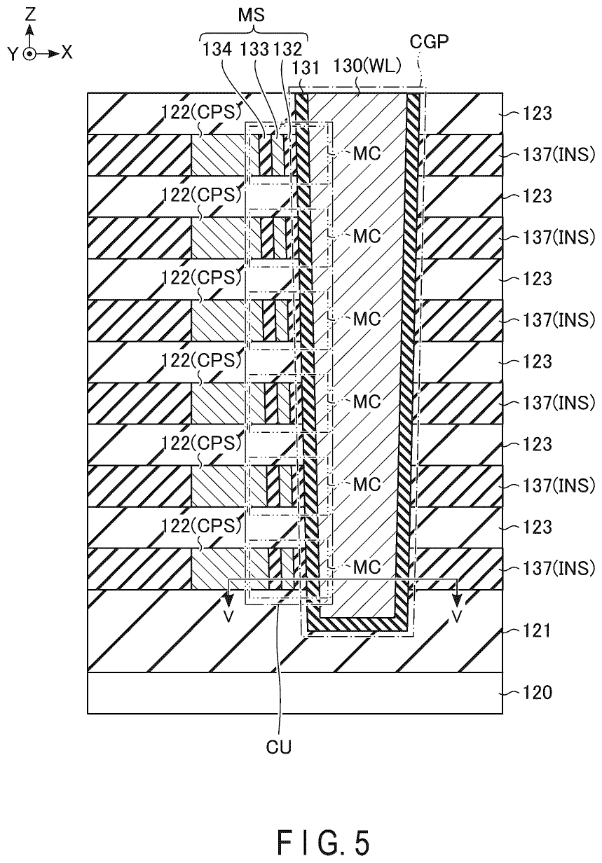

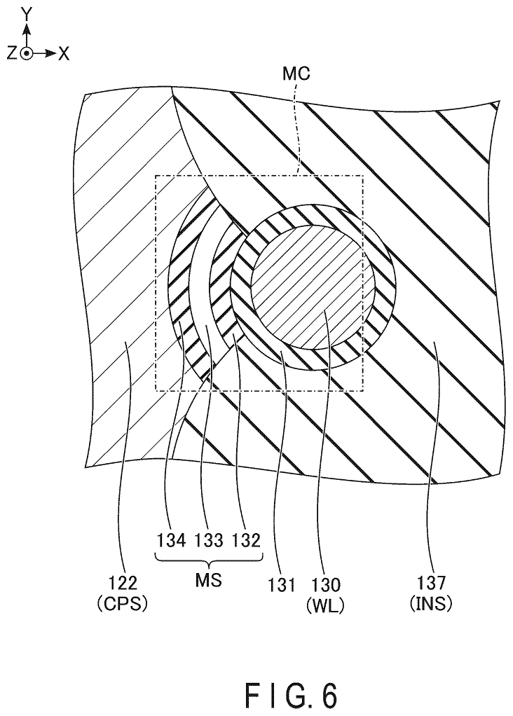

A cross-sectional structure of a conductive pillar CGP will be described with reference to FIGS. 5 and 6. FIG. 5 is a cross-sectional view taken along line IV-IV of FIG. 4 and showing an example of the cross-sectional structure of the memory cell array 17 according to the first embodiment. In FIG. 5, the cross-sectional structure of one conductive pillar CGP is mainly shown. FIG. 6 is a cross-sectional view taken along line V-V in FIG. 5 and showing an example of the cross-sectional structure of a memory cell transistor MC. More specifically, FIG. 6 shows a cross-sectional structure of a conductive pillar CGP in a layer parallel to the XY plane and including a semiconductor layer 122.

As shown in FIG. 5, the memory cell array 17 includes a substrate 120, insulator layers 121 and 123, semiconductor layers 122, insulators 137, a conductive pillar CGP, and memory structures MS. The insulators 137 corresponds to the insulators INS.

The substrate 120 is, for example, a p-type semiconductor. The insulator layer 121 is provided on the upper surface of the substrate 120. The substrate 120 and insulator layer 121 may include a circuit not shown. The circuit included in the substrate 120 and insulator layer 121 corresponds to, for example, the row decoder 18, the sense amplifier 19, or the like.

On the upper surface of the insulator layer 121, the semiconductor layers 122 and the insulator layers 123 are alternately stacked one by one. In the example shown in FIG. 5, six semiconductor layers 122 and six insulator layers 123 are alternately stacked one by one. In other words, the semiconductor layers 122 are stacked apart from each other above the substrate 120 in the Z direction. The number of semiconductor layers 122 corresponds to, for example, the number of bit lines BL.

The semiconductor layers 122 correspond to the semiconductors CPS and each have a (linear) portion extending in the Y direction. This portion functions as a channel of the NAND string NS. The insulator layers 121 and 123 contain silicon oxide, for example. The semiconductor layers 122 contain polysilicon, for example.

The insulators 137 have portions extending on the XY plane in the same layers as the semiconductor layers 122, and the portions correspond to the insulators INS. Note that the insulators 137 may have column portions extending in the Z direction and passing through the insulators INS spaced apart from each other in the Z direction.

The conductive pillar CGP extends in the Z direction so as to intersect the semiconductor layers 122 and insulator layers 123. The lower end of the conductive pillar CGP reaches the insulator layer 121. The upper end of the conductive pillar CGP aligns with, for example, the upper end of the uppermost insulator layer 123. The conductive pillar CGP is electrically coupled to the row decoder 18 to function as a word line WL.

In the same layer as each of the semiconductor layers 122, part of the side surface of the conductive pillar CGP is in contact with its corresponding insulator 137. Part of the side surface of the conductive pillar CGP in the same layer as each of the semiconductor layers 122, which is not in contact with the corresponding insulator 137, is in contact with the corresponding memory structure MS. The conductive pillar CGP includes a conductive film 130 and an insulator film 131. The memory structure MS includes an insulator film 132, a charge storage film 133, and an insulator film 134.

The conductor film 130 extends in the Z direction. For example, the upper end of the conductor film 130 aligns with, for example, the upper end of the uppermost insulator layer 123. The lower end of the conductor film 130 is included in a layer that is lower than the lowermost semiconductor layer 122. The conductor film 130 contains tungsten, for example. The conductive film 130 functions as interconnect (word line WL) coupled to the gate of the memory cell transistor MC.

The insulator film 131 covers the side and bottom surfaces of the conductor film 130. The insulator film 131 contains silicon oxide, for example. Note that the insulator film 131 may have a stacked structure including silicon oxide and aluminum oxide or hafnium silicate.

The insulator film 132 is provided between the semiconductor layer 122 and the insulator film 131 in the same layer as the semiconductor layer 122. The charge storage film 133 is provided between the semiconductor layer 122 and the insulator film 132 in the same layer as the semiconductor layer 122. The insulator film 134 is provided between the semiconductor layer 122 and the charge storage film 133 in the same layer as the semiconductor layer 122. The side surface of the insulator film 134 is in contact with the semiconductor layer 122. The insulator film 132 contains hafnium silicate, for example. The insulator film 134 contains silicon oxide, for example. The charge storage film 133 contains a material having a function of storing charges. Specifically, the charge storage film 133 may include a conductor such as silicon and metal. The charge storage film 133 may also include an insulator such as silicon nitride. If the charge storage film 133 includes a conductor such as silicon and metal, the memory cell transistor MC functions as an FG type memory cell transistor MC. If the charge storage film 133 includes an insulator such as silicon nitride, the memory cell transistor MC functions as a MONOS type memory cell transistor MC.

The conductive pillar CGP may function as a plurality of memory cell transistors MC coupled to the same word line WL. In other words, the conductive pillar CGP may function as one cell unit CU. Thus, the memory cell transistors MC in the cell unit CU are spaced apart from each other in the Z direction.

An example of the cross-sectional structure of a memory cell transistor MC will be described below with reference to FIG. 6.

As shown in FIG. 6, in the cross-section including the semiconductor layer 122, the conductive film 130 is provided, for example, at the center of the conductive pillar CGP. The insulator film 131 surrounds the side surface of the conductor film 130. The insulator film 132 surrounds a portion of the side surface of the insulator film 131 which is not in contact with the insulator INS (insulator 137). The charge storage film 133 surrounds the side surface of the insulator film 132. The insulator film 134 surrounds the side surface of the charge storage film 133. The semiconductor layer 122 surrounds the side surface of the insulator film 134. Thus, the insulator film 132, charge storage film 133, and insulator film 134 are provided only between the conductive pillar CGP and the semiconductor layer 122, and not provided between the conductive pillar CGP and the insulator INS.

The conductor film 130 is used as interconnect (word line WL) coupled to the gate of the memory cell transistor MC. The insulator films 131 and 132 are used as block insulating films of the memory cell transistor MC. The insulator film 134 is used as a tunnel insulating film of the memory cell transistor MC.

### 1.1.3.3 Cross-Sectional Structure of Conductive Pillar SGP

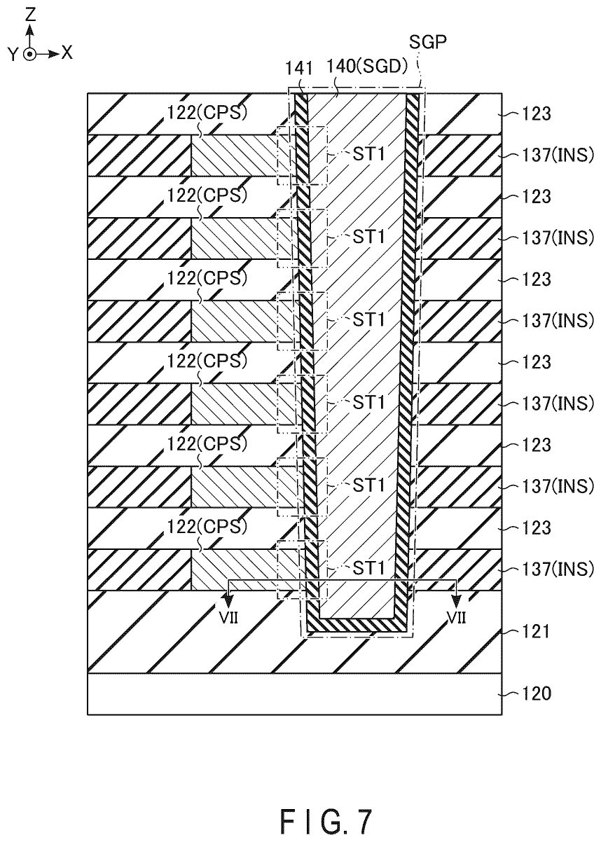

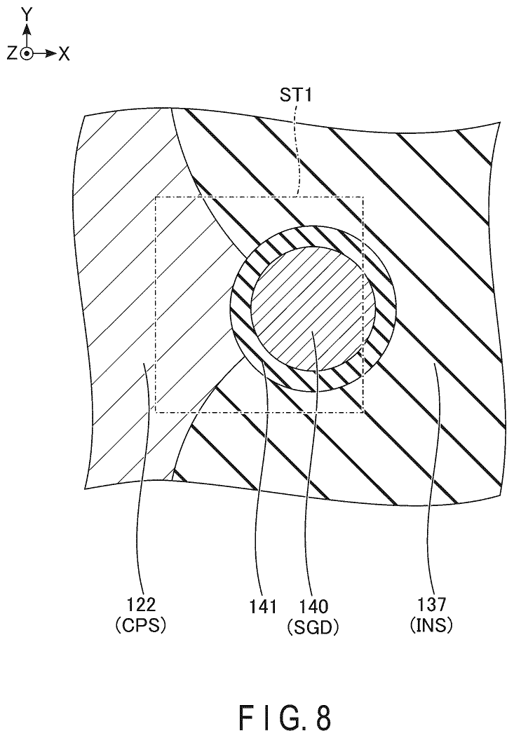

An example of the cross-sectional structure of the conductive pillar SGP will be described below with reference to FIGS. 7 and 8. FIG. 7 is a cross-sectional view taken along line VI-VI of FIG. 4 and showing an example of the cross-sectional structure of the memory cell array 17. In FIG. 7, the cross-sectional structure of one conductive pillar SGP that is in contact with the same insulator INS is mainly shown. FIG. 8 is a cross-sectional view taken along line VII-VII of FIG. 7 and showing an example of the cross-sectional structure of the selection transistor ST1. More specifically, FIG. 8 shows a cross-sectional structure of the conductive pillar SGP in a layer parallel to the XY plane and including the semiconductor layer 122.

As shown in FIG. 7, the memory cell array 17 further includes a conductive pillar SGP. The structures other than that of the conductive pillar SGP are equivalent to those shown in FIG. 5 and thus their description will be omitted.

The conductive pillar SGP extends in the Z direction so as to intersect a plurality of semiconductor layers 122 and insulator layers 123. The lower end of the conductive pillar SGP reaches the insulator layer 121. The upper end of the conductive pillar SGP aligns with, for example, the upper end of the uppermost insulator layer 123. The conductive pillar SGP is electrically coupled to the row decoder 18 to function as a select gate line SGD.

In the same layers as the semiconductor layers 122, a portion of the side surface of the conductive pillar SGP is in contact with the insulators INS (insulators 137). A portion of the side surface of the conductive pillar SGP in the same layers as the semiconductor layers 122, which is not in contact with the insulators INS, is in contact with the semiconductor layers 122. The conductive pillar SGP includes a conductive film 140 and an insulator film 141.

The conductor film 140 extends in the Z direction. The upper end of the conductor film 140 aligns with, for example, the upper end of the uppermost insulator layer 123. The lower end of the conductor film 140 is included in a layer that is lower than the lowermost semiconductor layer 122. The conductor film 140 contains tungsten, for example.

The insulator film 141 covers the side and bottom surfaces of the conductor film 140. The insulator film 141 contains silicon oxide, for example. Note that the insulator film 141 may have a stacked structure including silicon oxide and aluminum oxide or hafnium silicate.

An example of the cross-sectional structure of the selection transistor ST1 will be described below with reference to FIG. 8.

In the section including the semiconductor layer 122, the conductive film 140 is provided, for example, at the center of the conductive pillar SGP. The insulator film 141 surrounds the side surface of the conductor film 140. The semiconductor layer 122 surrounds part of the side surface of the insulator film 141. Part of the side surface of the insulator film 141 which is not surrounded by the semiconductor layer 122 is surrounded by the insulator 137.

The conductor film 140 is used as interconnect (select gate line SGD) coupled to the gate of the selection transistor ST1. The insulator film 141 is used as a block insulating film of the selection transistor ST1. Thus, the conductive pillar SGP may function as a plurality of select transistors ST1 coupled to the same select gate line SGD.

Although the cross-sectional structure of the conductive pillar SGP corresponding to the select gate line SGD has been described with reference to FIGS. 7 and 8, the conductive pillar SGP corresponding to the select gate line SGS also has the same cross-sectional structure as that of the conductive pillar SGP corresponding to the select gate line SGD.

### 1.2 Threshold Voltage Distributions of Memory Cells

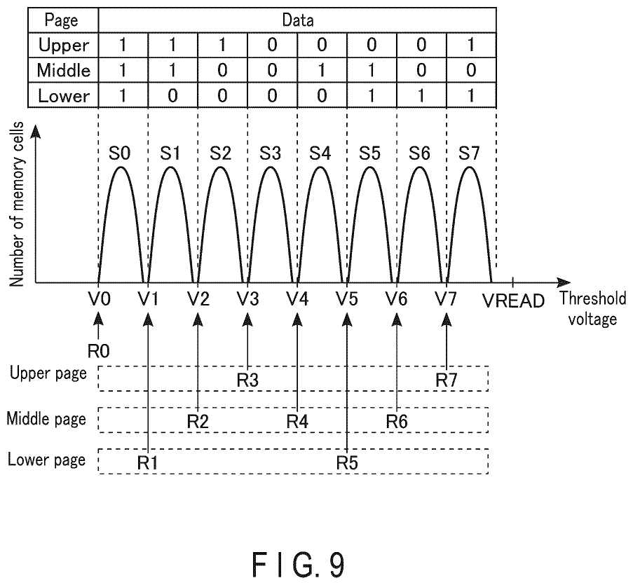

An example of the threshold voltage distributions of the memory cell transistors MC will be described below with reference to FIG. 9. FIG. 9 is a diagram showing the threshold voltage distributions and the data allocation in a case where the memory cell transistor MC is a TLC.

As shown in FIG. 9, in a case where the memory cell transistor MC is a TLC that stores 3-bit data, the distribution of the threshold voltages is divided into eight. The eight threshold voltage distributions (threshold voltage ranges) are referred to as S0 to S7 states in increasing order of threshold voltages.

In FIG. 9, voltages V0 to V7 are verify voltages used for program verify operations in the S0 to S7 states during write operations. Voltage VREAD is a voltage applied to the non-selected word line WL at the time of the read operation. When the voltage VREAD is applied to the gate of the memory cell transistor MC, the memory cell transistor MC is turned on regardless of data stored therein. The relationship between the voltages V0 to V7 and the voltage VREAD is V0<V1<V2<V3<V4<V5<V6<V7<VREAD. Note that the verify voltage V0 may be omitted.

The S0 state corresponds to the erase state of the memory cell transistor MC. The S1 to S7 states correspond to states in which charges are injected into the charge storage film of the memory cell transistor MC and data is written thereto. The threshold voltage of the memory cell transistor MC included in the S0 state is the voltage V0 or higher and lower than the voltage V1. The threshold voltage of the memory cell transistor MC included in each of the S1 to S6 states is the voltage V1 or higher and lower than the voltage V2 to the voltage V6 or higher and lower than the voltage V7. The threshold voltage of the memory cell transistor MC included in the S7 state is the voltage V7 or higher and lower than the voltage VREAD.

The set value of a verify voltage corresponding to each state and the set value of a read voltage may be the same or different. In order to simplify the description, it is assumed hereinafter that the verify voltage and the read voltage have the same set value.

Hereinafter, read operations using voltages V0 to V7 will be referred to as read operations R0 to R7, respectively. The read operation R0 determines whether the threshold voltage of the memory cell transistor MC is lower than the voltage V0. The read operation R1 determines whether the threshold voltage of the memory cell transistor MC is lower than the voltage V1. The read operation R2 determines whether the threshold voltage of the memory cell transistor MC is lower than the voltage V2. The read operation R3 determines whether the threshold voltage of the memory cell transistor MC is lower than the voltage V3. The same applies to the following.

As described above, the threshold voltage of each memory cell transistor MC belongs to one of the eight threshold voltage distributions. Thus, the memory cell transistors MC can be set in eight different states. If these states are allocated to binary data “000” to “111,” each memory cell transistor MC can store 3-bit data. Hereinafter, 3-bit data will be referred to as “Lower Bit,” “Middle Bit”, and “Upper Bit” in order from lower Bit. A set of Lower Bits stored in the memory cell transistors MC included in the same cell unit CU is referred to as “Lower Page Data,” a set of Middle Bits is referred to as “Middle Page Data” and a set of Upper Bits is referred to as “Upper Page Data”.

In the example shown in FIG. 9, data of “Upper Bit/Middle Bit/Lower Bit” is allocated to the memory cell transistors MC included in each state as shown below.
S0 state: “111” data
S1 State: “110” data
S2 state: “100” data
S3 state: “000” data
S4 state: “010” data
S5 state: “011” data
S6 state: “001” data
S7 state: “101” data

When the data thus allocated is read, the read operations R0 to R7 are performed. The Lower Bits are determined by the read operations R1 and R5. The Middle Bits are determined by the read operations R2, R4 and R6. The Upper Bits are determined by the read operations R3 and R7. The values of the Lower, Middle, and Upper bits are determined by two, three, and two read operations, respectively. Hereinafter, this data allocation will be referred to as “2-3-2 code”. Note that the data allocation to the S0 to S7 states is not limited to the 2-3-2 code.

### 1.3 Write Operation

Next is a description of a write operation. The write operation roughly includes a program operation and a program verify operation.

The program operation is an operation of injecting electrons into a charge storage film to increase the threshold voltage (or an operation of hardly injecting electrons into a charge storage film to maintain the threshold voltage). Hereinafter, the memory cell transistor MC that increases the threshold voltage will also be referred to as a “program-target memory cell transistor MC”. The memory cell transistor MC that does not increase the threshold voltage will also be referred to as a “program-inhibit memory cell transistor MC”.

The program verify operation is an operation of reading data and then determining whether the threshold voltage of the memory cell transistor MC has reached a target level after the program operation. Hereinafter, when the threshold voltage of the memory cell transistor MC reaches the target level, it will be referred to as “verification has passed” and when the threshold voltage does not reach the target level, it will be referred to as “verification has failed”. More specifically, for example, in the program verify operation, if the number of fail bits of the read data is equal to or larger than a preset reference value, it is determined that “verification has failed”. When the verification has failed, the threshold voltage of the memory cell transistor MC is increased to the target level by repeating the combination of the program operation and the program verify operation (referred to as a “program loop” hereinafter). The program-target memory cell transistor MC whose threshold voltage has reached the target level is inhibited from being programmed in the subsequent program loop. That is, the memory cell transistor MC whose programming has been completed is inhibited from being programmed.

Hereinafter, the write-target memory cell transistor MC will also be referred to as a “selected memory cell transistor MC”. The word line WL coupled to the selected memory cell transistor MC will also be referred to as a “selected word line WL”. For example, the program voltage applied to the selected word line WL during the program operation is stepped up each time the program loop is repeated. The threshold voltage of the selected memory cell transistor MC increases in accordance with the step-up width.

### 1.3.1 Multi-Pulse Write Operation

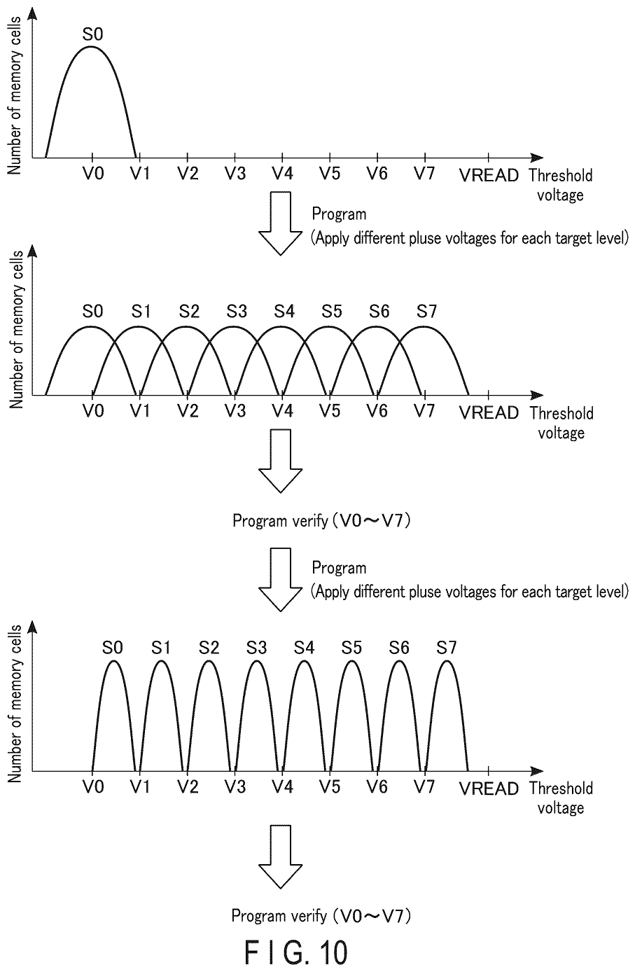

A multi-pulse write operation will be described below with reference to FIG. 10. FIG. 10 is a diagram showing an example of a change in the threshold voltage distributions of memory cell transistors that is performing a multi-pulse write operation.

The multi-pulse write operation is a write operation of continuously applying a plurality of pulse voltages (program voltages), which correspond to a plurality of target levels (states), to the selected word line WL in one program operation. Note that the wording “continuously” in this case includes an interval between pulse voltages. The voltage values of the pulse voltages vary according to the target levels (states). The memory cell transistor MC is in a writable state for a corresponding pulse voltage and is in a program inhibit state for the other pulse voltages by voltage control of the bit line BL. Using a pulse voltage corresponding to a target level, the threshold voltage of the memory cell transistor MC rises to a voltage value corresponding to the target level.

As shown in the upper graph of FIG. 10, for example, the threshold voltage distributions of a plurality of memory cell transistors MC before the start of the write operation is made in the S0 state.

As shown in the middle graph of FIG. 10, in one program operation, the different pulse voltages for each target level are applied to the selected word line WL. In the example shown in FIG. 10, eight pulse voltages respectively corresponding to the S0 to S7 states are applied. Thus, the threshold voltages of the memory cell transistors MC are divided into eight distributions respectively corresponding to the S0 to S7 states. For example, after a first program operation is performed, the threshold voltage distribution of each state has a relatively wide skirt, which overlaps the skirts of the threshold voltage distributions of the states adjacent thereto. For example, the threshold voltage distribution of the S1 state partially overlaps the threshold voltage distributions of the S0 and S2 states.

After the program operation, the program verify operation is performed. In the multi-pulse write operation, the program verify operation corresponding to each target level is continuously performed. In the example shown in FIG. 10, read operations R0 to R7 using voltages the voltages V0 to V7 respectively corresponding to the S0 to S7 states are performed in sequence. In the multi-pulse operation of executing programs for all the states in parallel, the program verify operation is also performed continuously for all the states.

If the verification has failed, then the program loop is repeated.

As shown in the lower graph of FIG. 10, for example, a second program operation is performed in the same manner as the first program operation. That is, a plurality of pulse voltages (program voltages) corresponding to a plurality of target levels (states) are applied to the selected word line WL. Note that in the second program operation, the pulse voltages are stepped up.

After the program operation, the program verify operation is performed. When the verification has passed, the multi-pulse write operation is terminated.

### 1.3.2 Grouping of States

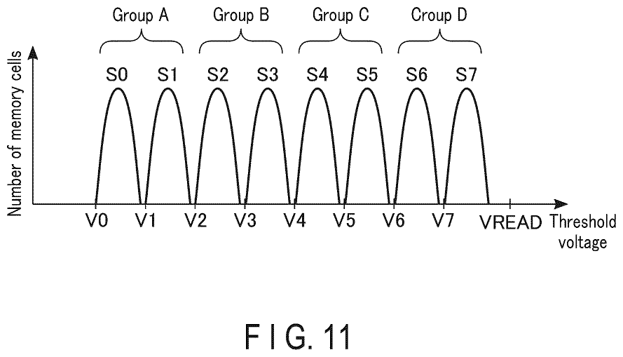

An example of grouping of the states in the multi-pulse write operation will be described below with reference to FIG. 11. FIG. 11 is a diagram showing an example of grouping of the states when the memory cell transistor MC is the TLC. Note that in the example shown in FIG. 11, the memory cell transistor MC is the TLC, but this is not a limitation. For example, the memory cell transistor MC may be the QLC or the PLC.

As shown in FIG. 11, when the memory cell transistor MC is the TLC, its threshold voltage distribution is divided into S0 to S7 states. In the first embodiment, when the write operation is performed, one or more states with adjacent threshold voltage distributions are formed as one group. In the example shown in FIG. 11, the S0 and S1 states are classified into group A, the S2 and S3 states are classified into group B, the S4 and S5 states are classified into group C, and the S6 and S7 states are classified into group D. Note that the number of groups is arbitrary. The number of groups has only to be smaller than the number of states. The combination of groups is not limited to the example shown in FIG. 11.

### 1.3.3 Voltage of Each Interconnect in Multi-Pulse Write Operation

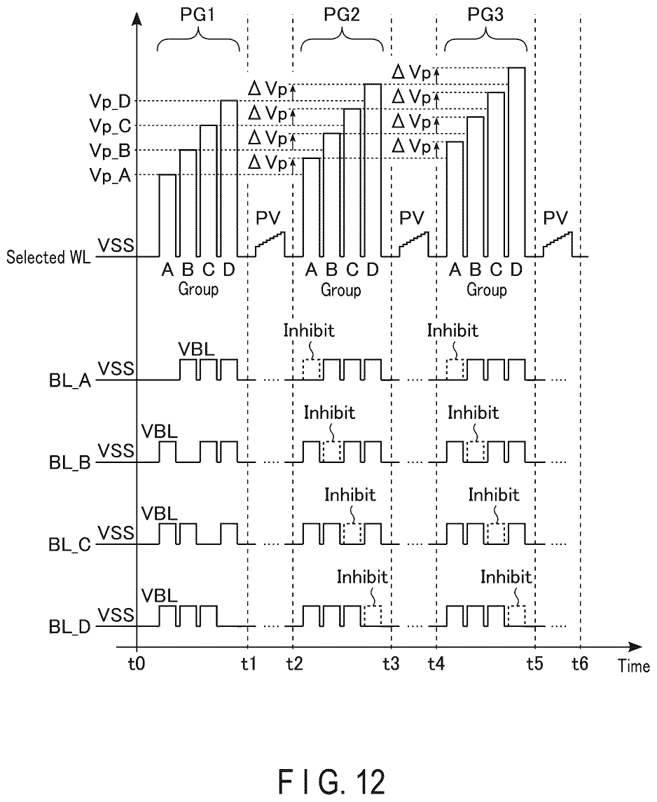

An example of the voltage of each interconnect in the multi-pulse write operation will be described below with reference to FIG. 12. FIG. 12 is a timing chart showing an example of the voltage of each interconnect in the multi-pulse write operation. FIG. 12 shows the voltages of the selected word line and the bit lines BL. Note that in the example shown in FIG. 12, the voltages of the bit lines BL in the program verify operation are omitted in order to simplify the description.

As shown in FIG. 12, a first program operation PG1 is performed during the period of time t0 to t1. The row decoder 18 continuously applies to the selected word line WL a pulse voltage Vp_A corresponding to group A, a pulse voltage Vp_B corresponding to group B, a pulse voltage Vp_C corresponding to group C, and a pulse voltage Vp_D corresponding to group D. For example, group A is selected during the application of the pulse voltage Vp_A, group B is selected during the application of the pulse voltage Vp_B, group C is selected during the application of the pulse voltage Vp_C, and group D is selected during the application of the pulse voltage Vp_D. For example, the relationship among the pulse voltages Vp_A, Vp_B, Vp_C, and Vp_D is Vp_A<Vp_B<Vp_C<Vp_D. Note that the order in which the pulse voltages are applied is arbitrary. For example, the row decoder 18 may apply the pulse voltages Vp_D, Vp_C, Vp_B, and Vp_A to the selected word line WL in that order presented.

The sense amplifier 19 applies a voltage VSS to a bit line BL_A corresponding to group A while the pulse voltage Vp_A is applied to the selected word line WL. In the NAND string NS corresponding to group A, the selection transistor ST1 is turned on. Thus, the threshold voltage of the selected memory cell transistor MC of group A increases in accordance with a difference between the voltage Vp_A and the voltage VSS. In addition, the sense amplifier 19 applies a voltage VBL to a bit lines BL_B corresponding to group B, a bit line BL_C corresponding to group C, and a bit line BL_D corresponding to group D. The voltage VBL is a positive voltage at which the selection transistor ST1 is cut off. In the NAND strings NS corresponding to groups B, C, and D, the selection transistor ST1 is cut off. Thus, the NAND strings NS corresponding to groups B, C, and D are brought into a floating state. The selected memory cell transistors MC corresponding to groups B, C, and D are inhibited from being programmed by channel boost.

The sense amplifier 19 applies the voltage VSS to the bit line BL_B during the application of the pulse voltage Vp_B to the selected word line WL. The sense amplifier 19 also applies the voltage VBL to the bit lines BL_A, BL_C, and BL_D. Thus, the threshold voltage of the selected memory cell transistor MC of group B increases in accordance with a difference between the voltage Vp_B and the voltage VSS. The amount of increased of the threshold voltage of the selected memory cell transistor MC of group B is larger than that of increase of the threshold voltage of the selected memory cell transistor MC of group A. In addition, the selected memory cell transistors MC of groups A, C, and D are inhibited from being programmed.

The sense amplifier 19 applies the voltage VSS to the bit line BL_C during the application of the pulse voltage Vp_C to the selected word line WL. The sense amplifier 19 also applies the voltage VBL to the bit lines BL_A, BL_B, and BL_D. Thus, the threshold voltage of the selected memory cell transistor MC of group C increases in accordance with a difference between the voltage Vp_C and the voltage VSS. The amount of increase of the threshold voltage of the selected memory cell transistor MC of group C is larger than that of increase of the threshold voltage of the selected memory cell transistor MC of group B. In addition, the selected memory cell transistors MC of groups A, B, and D are inhibited from programmed.

The sense amplifier 19 applies the voltage VSS to the bit line BL_D during the application of the pulse voltage Vp_D to the selected word line WL. The sense amplifier 19 also applies the voltage VBL to the bit lines BL_A, BL_B, and BL_C. Thus, the threshold voltage of the selected memory cell transistor MC of group D increases in accordance with a difference between the voltage Vp_D and the voltage VSS. The amount of increase of the threshold voltage of the selected memory cell transistor MC of group D is larger than that of increase of the threshold voltage of the selected memory cell transistor MC of group C. In addition, the selected memory cell transistors MC of groups A, B, and C are inhibited from being programmed.

During the period of time t1 to t2, the program verify operation PV is performed. The row decoder 18 applies voltages V0 to V7 in sequence to the selected word line WL. In other words, the read operations R0 to R7 are performed in sequence. Note that the order of application of the voltages V0 to V7 is arbitrary. The selected memory cell transistor MC whose threshold voltage has reached the target level (the selected memory cell transistor MC whose programming has been completed) is inhibited from being programmed in the subsequent program loop.

During the period of time t2 to t3, a second program operation PG2 is performed. The row decoder 18 continuously applies voltages, which are obtained by stepping up the pulse voltages Vp_A, Vp_B, Vp_C, and Vp_D to the selected word line WL. The step-up voltages ΔVp added to the pulse voltages are the same. That is, the pulse voltages have the same step-up width. The step-up voltages ΔVp are positive voltages. More specifically, the row decoder 18 continuously applies the stepped-up pulse voltages Vp_A+ΔVp, Vp_B+ΔVp, Vp_C+ΔVp, and Vp_D+ΔVp to the selected word line WL. Note that in the example shown in FIG. 12, the same step-up voltage ΔVp is added to each of the pulse voltages Vp_A, Vp_B, Vp_C, and Vp_D, but the step-up voltage may vary from pulse voltage to pulse voltage.

During the period of application of the pulse voltage Vp_A+ΔVp to the selected word line WL, the sense amplifier 19 applies the voltage VSS to the bit line BL_A corresponding to the selected memory cell transistor MC that is to be programmed, and applies the voltage VBL to the bit line BL_A corresponding to the selected memory cell transistor MC that is inhibited from being programmed. The sense amplifier 19 also applies the voltage VBL to the bit lines BL_B, BL_C, and BL_D.

During the period of application of the pulse voltage Vp_B+ΔVp to the selected word line WL, the sense amplifier 19 applies the voltage VSS to the bit line BL_B corresponding to the selected memory cell transistor MC that is to be programmed, and applies the voltage VBL to the bit line BL_B corresponding to the selected memory cell transistor MC that is inhibited from being programmed. The sense amplifier 19 also applies the voltage VBL to the bit lines BL_A, BL_C, and BL_D.

During the period of application of the pulse voltage Vp_C+ΔVp to the selected word line WL, the sense amplifier 19 applies the voltage VSS to the bit line BL_C corresponding to the selected memory cell transistor MC that is to be programmed, and applies the voltage VBL to the bit line BL_C corresponding to the selected memory cell transistor MC that is inhibited from being programmed. The sense amplifier 19 also applies the voltage VBL to the bit lines BL_A, BL_B, and BL_D.

During the period of application of the pulse voltage Vp_D+ΔVp to the selected word line WL, the sense amplifier 19 applies the voltage VSS to the bit line BL_D corresponding to the selected memory cell transistor MC that is to be programmed, and applies the voltage VBL to the bit line BL_D corresponding to the selected memory cell transistor MC that is inhibited from being programmed. The sense amplifier 19 also applies the voltage VBL to the bit lines BL_A, BL_B, and BL_C.

Like during the period of time t1 to t2, during the period of time t3 to t4, the program verify operation PV is performed.

During the period of time t4 to t5, a third program operation PG3 is performed. The row decoder 18 continuously applies voltages, which are obtained by stepping up the pulse voltages Vp_A+ΔVp, Vp_B+ΔVp, Vp_C+ΔVp, and Vp_D+ΔVp, to the selected word line WL. More specifically, the row decoder 18 continuously applies the pulse voltages Vp_A+2ΔVp, Vp_B+2ΔVp, Vp_C+2ΔVp, and Vp_D+2ΔVp to the selected word line WL. The step-up voltage in the third program operation PG3 may be smaller than the voltage ΔVp.

The sense amplifier 19 applies a voltage to each bit line BL as in the second program operation PG2.

Like during the period of time t1 to t2, during the period of time t5 to t6, the program verify operation PV is performed. If the verify has passed, the multi-pulse write operation is terminated.

### 1.3.4 Flow of Multi-Pulse Write Operation

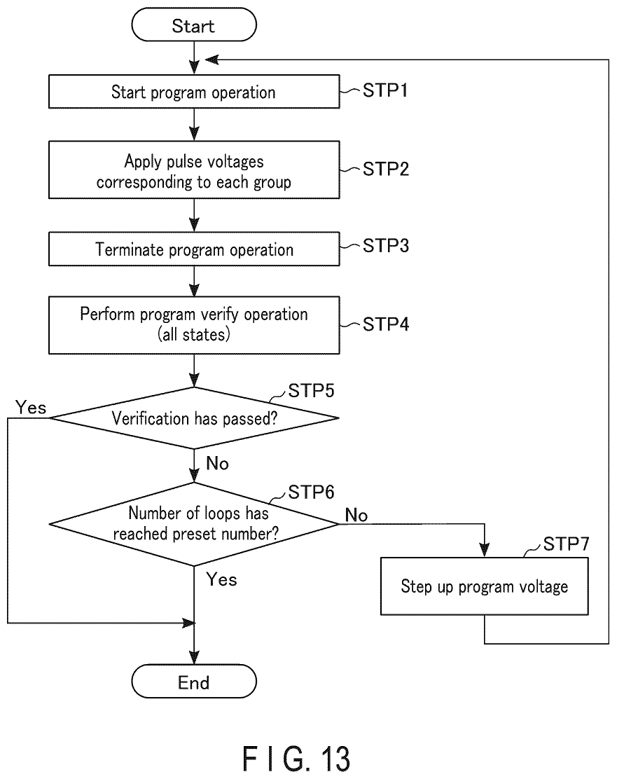

An example of a flow of the multi-pulse write operation will be described below with reference to FIG. 13. FIG. 13 is a flowchart showing an example of the flow of the multi-pulse write operation.

As shown in FIG. 13, upon receiving a write instruction about the multi-pulse write operation from the memory controller 2, the sequencer 14 starts a program operation (STP1).

In the program operation, the row decoder 18 applies a plurality of pulse voltages corresponding to each group to the selected word line WL (STP2). More specifically, for example, in a case where a plurality of states are grouped into groups A to D, the row decoder 18 first applies a pulse voltage for group A to the selected word line WL. At this time, the threshold voltage of the selected memory cell transistor MC to be programmed in group A is increased. Then, the row decoder 18 applies a pulse voltage for group B to the selected word line WL. At this time, the threshold voltage of the selected memory cell transistor MC to be programmed in group B is increased. Then, the row decoder 18 applies a pulse voltage for group C to the selected word line WL. At this time, the threshold voltage of the selected memory cell transistor MC to be programmed in group C is increased. Then, the row decoder 18 applies a pulse voltage for group D to the selected word line WL. At this time, the threshold voltage of the selected memory cell transistor MC to be programmed in group D is increased.

The sequencer 14 terminates the program operation (STP3).

Then, the sequencer 14 performs a program verify operation of all the states (STP4). For example, when the memory cell transistor MC is the TLC, the sequencer 14 sequentially performs the read operations R0 to R7 corresponding to the verify voltages V0 to V7.

If the verification has passed (Yes in STP5), the sequencer 14 terminates the multi-pulse write operation.

If the verification has failed (No in STP5), the sequencer 14 checks whether the number of program loops has reached a preset number.

If the number of program loops has reached the preset number (Yes in STP6), the sequencer 14 terminates the multi-pulse write operation. For example, the sequencer 14 notifies the memory controller 2 that the write operation has failed.

If the number of program loops has not reached the preset number (No in STP6), the sequencer 14 steps up each pulse voltage (STP7). The sequencer 14 proceeds to step STP1 and performs the next program loop.

### 1.4 Modification to Grouping of States

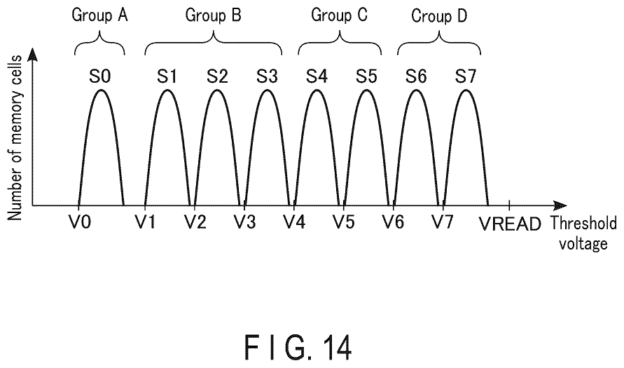

A modification to the grouping of states in the write operation will be described below with reference to FIG. 14. FIG. 14 is a diagram showing a modification to the grouping of states in a case where the memory cell transistor MC is the TLC.

When the memory cell transistor MC is the TLC, the threshold voltage distributions are divided into S0 to S7 states. For example, the S0 state is more susceptible to read disturb than the other states. That is, the threshold voltage of the memory cell transistor MC in the S0 state is more likely to increase than that of the memory cell transistor MC in each of the other states due to read disturbance. Thus, a margin for the increase of the threshold voltage may be provided between the S0 and S1 states. In this case, as shown in FIG. 14, the S0 state may be designated as group A, the S1, S2, and S3 states may be designated as group B, the S4 and S5 states may be designated as group C, and the S6 and S7 states may be designated as group D.

### 1.5 Advantageous Effect of First Embodiment

The semiconductor memory device 1 according to the first embodiment can improve in its processing capacity. This advantageous effect will be described in detail below.

For example, when a plurality of memory cell transistors MC in the cell unit CU are stacked apart from each other in the Z direction, interference between adjacent cells in the upper and lower layers greatly affects the write operation. For example, during the program operation, a multi-pulse write operation of applying to the selected word line WL a plurality of pulse voltages corresponding to each of the states is effective in reducing the inter-cell interference effect because the write operations of all the states are performed in parallel. However, the number of pulses increases and accordingly the processing time of the write operations increases.

In contrast, with the configuration of the semiconductor memory device 1 according to the first embodiment, the channel (semiconductor CPS) of the NAND string NS can be formed on the XY plane parallel to the substrate. In addition, a cell unit CU can be configured to include a plurality of memory cell transistors MC which are stacked apart from each other in the Z direction and whose gates are coupled in common to the word line WL. In addition, a multi-pulse write operation can be performed to group adjacent states and apply a plurality of pulse voltages corresponding to each group continuously to the selected word line WL. Thus, the semiconductor memory device 1 can reduce the number of pulses in one program operation. The semiconductor memory device 1 can also suppress an increase in the processing time of the write operation. Therefore, the semiconductor memory device 1 can improve in its processing capacity.

### 2. Second Embodiment

Next is a description of a second embodiment. The second embodiment is directed to a multi-pulse write operation different from that of the first embodiment. Hereinafter, a description will be made mainly on points different from the first embodiment.

### 2.1 Multi-Pulse Write Operation

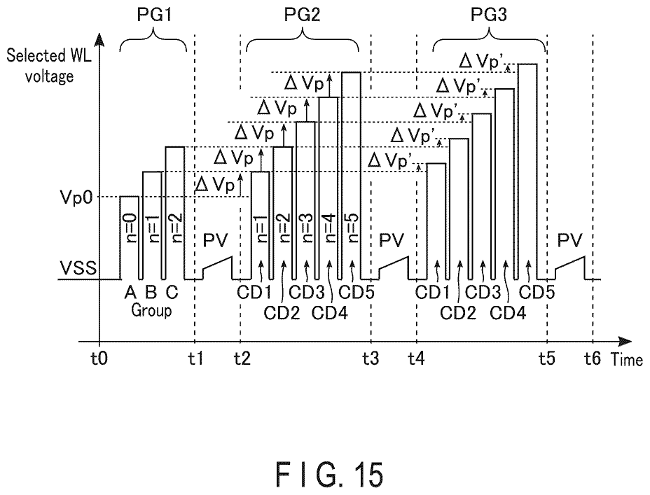

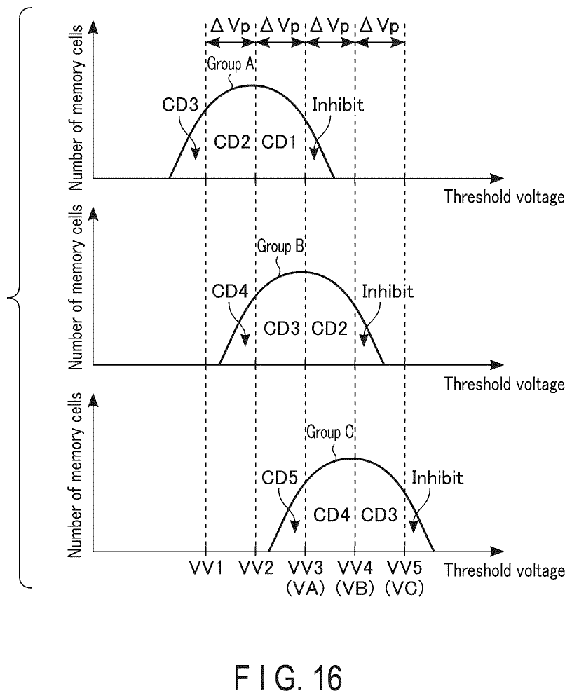

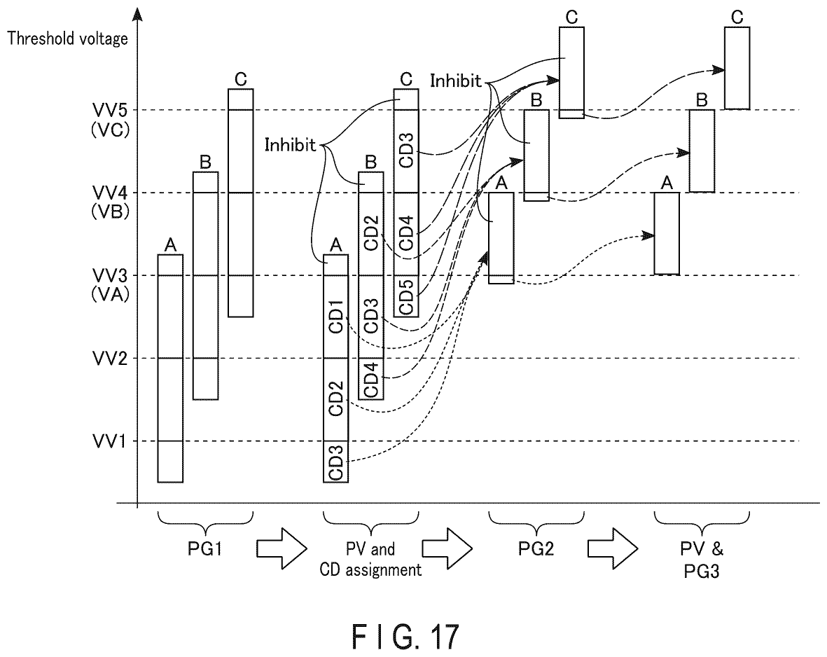

An example of the multi-pulse write operation will be described with reference to FIGS. 15 to 17. FIG. 15 is a timing chart showing an example of voltages of a selected word line WL in the multi-pulse write operation. FIG. 16 is a diagram showing an example of pulse voltage application conditions in the multi-pulse write operation. FIG. 16 shows the threshold voltage distributions for each group after a first program operation PG1. FIG. 17 is a diagram showing a transition of the threshold voltage distributions for each group in the multi-pulse write operation. In FIGS. 15 to 17, three groups (groups A, B, and C) are exemplified. Each of the groups includes one state or adjacent states.

In the multi-pulse write operation of the second embodiment, a difference in threshold voltage between the groups and a potential difference of the step-up voltages ΔVp are set to be the same. The pulse voltage is stepped up by voltage ΔVp. The sequencer 14 predicts a pulse voltage required for the next program operation based on the result of a program verify operation PV. The sequencer then reconfigures the groups (changes the configuration). More specifically, the sequencer 14 divides the threshold voltage distribution of each group into a plurality of sections according to the next required pulse voltage conditions. In the next (second) program operation PG, write operations are performed at a time for the sections of a plurality of groups in which the same pulse voltage conditions are used. That is, in the second and subsequent program operations, grouping is performed for each section of the same pulse voltage conditions.

As shown in FIG. 15, the first program operation PG1 is performed during the period of time t0 to t1. The pulse voltage corresponding to each group is stepped up by ΔVp. If the initial value of the pulse voltage is, for example, Vp0, the pulse voltage of each group can be expressed as Vp0+nΔVp (n is an integer larger than or equal to 0). In group A, n is equal to 0. In group B, n is equal to 1. In group C, n is equal to 2. More specifically, the row decoder 18 continuously applies to the selected word line WL the pulse voltage Vp0 corresponding to group A, the pulse voltage Vp0+ΔVp corresponding to group B and the pulse voltage Vp0+2ΔVp corresponding to group C.

The program verify operation PV is performed during the period of time t1 to t2.

As shown in FIGS. 16 and 17, after the first program operation PG1, the threshold voltage distributions of a plurality of memory cell transistors MC are divided into groups A, B, and C. For example, the threshold voltages of the distribution become higher in the order of groups A, B, and C. Note that the threshold voltage distributions of adjacent groups may partially overlap each other.

Voltages VV1 to VV5 indicate verify voltages. The relationship between the voltages VV1 to VV5 is VV1<VV2<VV3<VV4<VV5. In addition, for example, a voltage difference between the voltage VV2 and the voltage VV1, a voltage difference between the voltage VV3 and the voltage VV2, a voltage difference between the voltage VV4 and the voltage VV3, and a voltage difference between the voltage VV5 and the voltage VV4 are each the voltage ΔVp. That is, the relationship among the voltages VV1 to VV5 and the voltage ΔVp is VV2−VV1=VV3−VV2=VV4−VV3=VV5−VV4=ΔVp. For example, the verify voltages VV1 to VV5 are obtained by varying, by a factor of more than one, the difference ΔVp between the pulse voltage Vp0 used in the program operation of a first program loop and the pulse voltage Vp0+ΔVp used in the program operation of a second program loop. For example, the voltage VV3 is the verify voltage VA of the threshold voltage distribution of group A. The voltage VV4 is the verify voltage VB of the threshold voltage distribution of group B. The voltage VV5 is the verify voltage VC of the threshold voltage distribution of group C.

Based on the result of the program verify operation PV, the sequencer 14 divides the threshold voltage distribution of each group into a plurality of sections corresponding to the verify voltages. Then, it sets the conditions CD of a pulse voltage in the next program operation for each of the sections.

For example, in group A, the memory cell transistor MC in the section whose voltage is higher than voltage VV3 (voltage VA) reaches a target level, and is therefore inhibited from being programmed in the second program operation PG2. The condition CD1 of the pulse voltage is set to the memory cell transistor MC in the section whose voltage is higher than voltage VV2 and is equal to or lower than voltage VV3. The condition CD2 of the pulse voltage is set to the memory cell transistor MC in the section whose voltage is higher than voltage VV1 and is equal to or lower than voltage VV2. The condition CD3 of the pulse voltage is set to the memory cell transistor MC in the section whose voltage is equal to or lower than voltage VV1.

For example, in group B, the memory cell transistor MC in the section whose voltage is higher than voltage VV4 (voltage VB) reaches a target level, and is therefore inhibited from being programmed in the second program operation PG2. The condition CD2 of the pulse voltage is set to the memory cell transistor MC in the section whose voltage is higher than voltage VV3 and is equal to or lower than voltage VV4. The condition CD3 of the pulse voltage is set to the memory cell transistor MC in the section whose voltage is higher than voltage VV2 and is equal to or lower than voltage VV3. The condition CD4 of the pulse voltage is set to the memory cell transistor MC in the section whose voltage is equal to or lower than voltage VV2.

For example, in group C, the memory cell transistor MC in the section whose voltage is higher than voltage VV5 (voltage VC) reaches a target level, and is therefore inhibited from being programmed in the second program operation PG2. The condition CD3 of the pulse voltage is set to the memory cell transistor MC in the section whose voltage is higher than voltage VV4 and is equal to or lower than voltage VV5. The condition CD4 of the pulse voltage is set to the memory cell transistor MC in the section whose voltage is higher than voltage VV3 and is equal to or lower than voltage VV4. The condition CD5 of the pulse voltage is set to the memory cell transistor MC in the section whose voltage is equal to or lower than voltage VV3.

As shown in FIG. 15, n is set to be equal to 1 (n=1) as the condition CD1. The pulse voltage of the condition CD1 is voltage Vp0+ΔVp. The pulse voltage Vp0+ΔVp of the condition CD1 is a voltage obtained by stepping up the voltage Vp0, which corresponds to group A in the first program operation PG1, by the voltage ΔVp. In the second program operation PG2, the threshold voltage of the memory cell transistor MC divided into the condition CD1 of group A is increased based on the pulse voltage Vp0+ΔVp.

As the condition CD2, n is set to be equal to 2 (n=2). The pulse voltage of the condition CD2 is voltage Vp0+2ΔVp. The pulse voltage Vp0+2ΔVp of the condition CD2 is a voltage obtained by stepping up the voltage Vp0, which corresponds to group A in the first program operation PG1, by the voltage 2ΔVp, and is the same as a voltage obtained by stepping up the pulse voltage Vp0+ΔVp, which corresponds to group B in the first program operation PG1, by the voltage ΔVp. In the second program operation PG2, the threshold voltage of the memory cell transistor MC divided into the condition CD2 of groups A and B is increased based on the pulse voltage Vp0+2ΔVp.

As the condition CD3, n is set to be equal to 3 (n=3). The pulse voltage of the condition CD3 is voltage Vp0+3ΔVp. The pulse voltage Vp0+3ΔVp of the condition CD3 is a voltage obtained by stepping up the voltage Vp0, which corresponds to group A in the first program operation PG1, by the voltage 3ΔVp, and is the same as a voltage obtained by stepping up the pulse voltage Vp0+ΔVp, which corresponds to group B in the first program operation PG1, by the voltage 2ΔVp. In addition, the pulse voltage Vp0+3ΔVp of the condition CD3 is the same as a voltage obtained by stepping up the pulse voltage Vp0+2ΔVp, which corresponds to group C in the first program operation PG1, by the voltage ΔVp. In the second program operation PG2, the threshold voltage of the memory cell transistor MC divided into the condition CD3 of groups A, B, and C is increased based on the pulse voltage Vp0+3ΔVp.

As the condition CD4, n is set to be equal to 4 (n=4). The pulse voltage of the condition CD4 is voltage Vp0+4ΔVp. The pulse voltage Vp0+4ΔVp of the condition CD4 is a voltage obtained by stepping up the voltage Vp0+ΔVp, which corresponds to group B in the first program operation PG1, by the voltage 3ΔVp, and is the same as a voltage obtained by stepping up the pulse voltage Vp0+2ΔVp, which corresponds to group C in the first program operation PG1, by the voltage 2ΔVp. In the second program operation PG2, the threshold voltage of the memory cell transistor MC divided into the condition CD4 of groups B and C is increased based on the pulse voltage Vp0+4ΔVp.

As the condition CD5, n is set to be equal to 5 (n=5). The pulse voltage of the condition CD5 is voltage Vp0+5ΔVp. The pulse voltage Vp0+5ΔVp of the condition CD5 is a voltage obtained by stepping up the voltage Vp0+2ΔVp, which corresponds to group C in the first program operation PG1, by the voltage 3ΔVp. In the second program operation PG2, the threshold voltage of the memory cell transistor MC divided into the condition CD5 of group C is increased based on the pulse voltage Vp0+5ΔVp.

As shown in FIG. 15, the second program operation PG2 is performed during the period of time t2 to t3. Based on the result of the program verify operation PV, the sequencer 14 performs grouping again for each of the conditions CD1 to CD5 of the pulse voltages applied in the second program operation PG2 (reassign the groups or change the configuration of the groups). More specifically, the sequencer 14 sets as one group a plurality of memory cell transistors MC to which the condition CD1 of group A is applied, sets as one group a plurality of memory cell transistors MC to which the condition CD2 of groups A and B is applied, sets as one group a plurality of memory cell transistors MC to which the condition CD3 of groups A, B, and C is applied, sets as one group a plurality of memory cell transistors MC to which the condition CD4 of groups B and C is applied, and sets as one group a plurality of memory cell transistors MC to which the condition CD5 of group C is applied. The row decoder 18 applies a plurality of pulse voltages corresponding to the conditions CD1 to CD5 to the selected word line WL.

As shown in FIG. 17, the width of the threshold voltage distribution of each group is narrowed by the second program operation PG2. For example, the threshold voltages of most of the memory cell transistors MC reach the target level.

As shown in FIG. 15, the program verify operation PV is performed during the period of time t3 to t4. The memory cell transistor MC to be programmed, the threshold voltage of which has reached the target level, is inhibited from being programmed in the third program operation PG3.

During the period of time t4 to t5, the third program operation PG3 is performed. The row decoder 18 applies to the selected word line WL a plurality of pulse voltages corresponding to the conditions CD1 to CD5. For example, in the third program operation PG3, the lower end of the threshold voltage distribution of each group rises to the vicinity of the target level and thus the step-up voltage is decreased. The step-up voltage is defined as voltage ΔVp′, for example. The voltage ΔVp′ is a positive voltage that is lower than the voltage ΔVp. More specifically, voltage Vp0+ΔVp+ΔVp′ is set as the pulse voltage of the condition CD1. Voltage Vp0+2ΔVp+ΔVp′ is set as the pulse voltage of the condition CD2. Voltage Vp0+3ΔVp+ΔVp′ is set as the pulse voltage of the condition CD3. Voltage Vp0+4ΔVp+ΔVp′ is set as the pulse voltage of the condition CD4. Voltage Vp0+5ΔVp+ΔVp′ is set as the pulse voltage of the condition CD5. The sequencer 14 may perform grouping again based on the result of the program verify operation PV.

During the period of time t5 to t6, the program verify operation PV is performed. When the verification has passed, the multi-pulse write operation is terminated.

### 2.2 Advantageous Effect of Second Embodiment

The configuration of the semiconductor memory device 1 according to the second embodiment can bring about the same advantageous effect as that of the first embodiment.

The configuration of the semiconductor memory device 1 also makes it possible to set a difference in the threshold voltage between the groups and a potential difference of the step-up voltage ΔVp to be the same. In the semiconductor memory device 1, a pulse voltage required for the next program operation can be predicted based on the result of the program verify operation PV. In the next program operation, the configuration of a group can be changed for each section using the same pulse voltage condition. Thus, the application of pulse voltages of the same voltage value can be suppressed, and the number of pulses in the multi-pulse writing operation can be reduced. Therefore, the semiconductor memory device 1 can improve in its processing capacity.

### 3. Third Embodiment

Next is a description of a third embodiment. The third embodiment is directed to a multi-pulse write operation different from that of each of the first and second embodiments. Hereinafter, a description will be made mainly on points different from the first and second embodiments.

### 3.1 Grouping of States

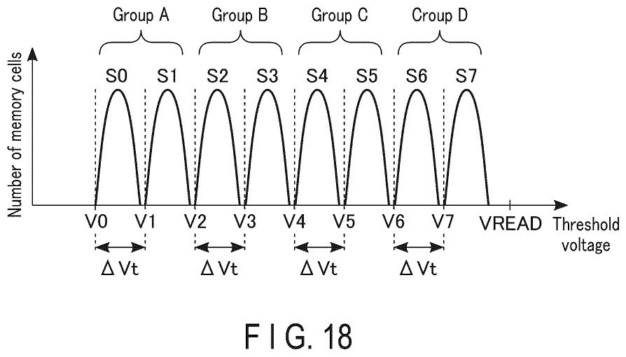

First, an example of grouping of states in a write operation will be described with reference to FIG. 18. FIG. 18 is a diagram showing an example of grouping of states when the memory cell transistor MC is the TLC. Note that in the example shown in FIG. 18, the memory cell transistor MC is the TLC, but it may be the QLC or the PLC.

As shown in FIG. 18, for example, group A includes S0 and S1 states. The potential difference between the threshold voltage distribution in the S0 state and that in the S1 state is, for example, ΔVt. That is, the relationship among voltages V0, V1, and ΔVt is V1−V0=ΔVt. Group B includes S2 and S3 states. As in group A, the potential difference between the threshold voltage distribution in the S2 state and that in the S3 state is ΔVt. That is, the relationship among voltages V2, V3, and ΔVt is V3−V2=ΔVt. Group C includes S4 and S5 states. As in group A, the potential difference between the threshold voltage distribution in the S4 state and that in the S5 state is ΔVt. That is, the relationship among voltages V4, V5, and ΔVt is V5−V4=ΔVt. Group D includes S6 and S7 states. As in group A, the potential difference between the threshold voltage distribution in the S6 and that in the S7 state is ΔVt. That is, the relationship among voltages V6, V7, and ΔVt is V7−V6=ΔVt.

### 3.2 Multi-Pulse Write Operation

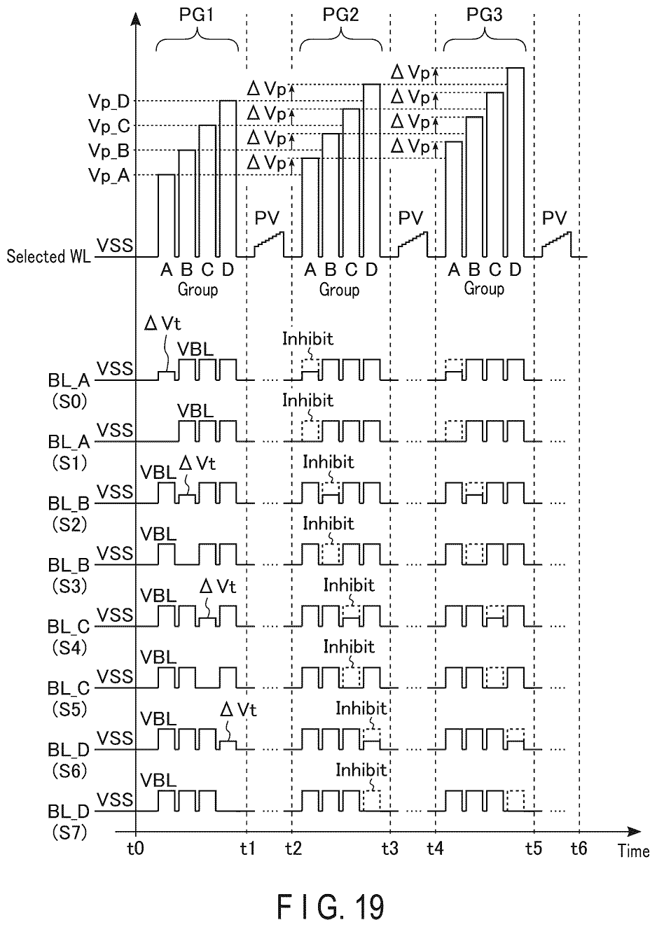

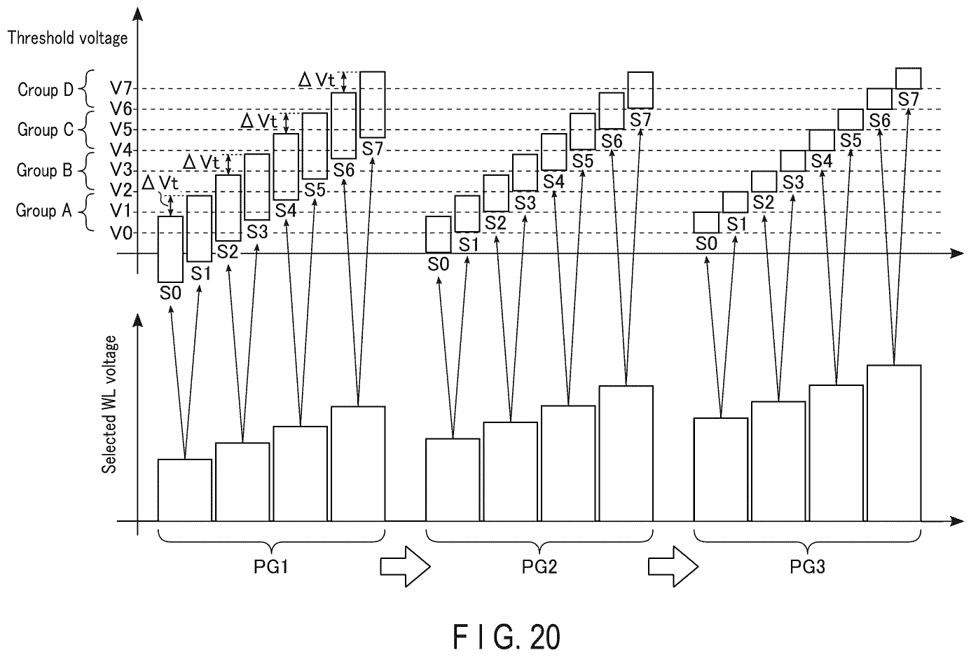

An example of a multi-pulse write operation will be described with reference to FIGS. 19 and 20. FIG. 19 is a timing chart showing an example of the voltage of each interconnect in the write operation. FIG. 19 also shows voltages of the selected word line and bit lines BL. Note that in the example shown in FIG. 19, the voltages of the bit lines BL in the program verify operation are omitted in order to simplify the description. FIG. 20 is a diagram showing a transition of the threshold voltage distributions for each state in the multi-pulse write operation.

As shown in FIG. 19, the voltage applied to the selected word line WL during the period of time t0 to t6 is the same as that described with reference to FIG. 12 of the first embodiment. In the third embodiment, in the program operation, different voltages are applied to the bit lines BL corresponding to different states included in the same group.

During the period of time t0 to t1, the sense amplifier 19 applies a voltage ΔVt to the bit line BL_A corresponding to the S0 state of group A during the period of application of the pulse voltage Vp_A to the selected word line WL. The voltage ΔVt is higher than the voltage VSS and lower than the voltage VBL. The sense amplifier 19 also applies the voltage VSS to the bit line BL_A corresponding to the S1 state of group A. In the NAND string NS corresponding to group A, the selection transistor ST1 is turned on. Thus, the threshold voltage of the selected memory cell transistor MC corresponding to the S0 state of group A rises in accordance with a voltage difference between the voltage Vp_A and the voltage ΔVt. The threshold voltage of the selected memory cell transistor MC corresponding to the S1 state of group A rises in accordance with the voltage difference between the voltage Vp_A and the voltage VSS. As shown in FIG. 20, the amount of rise of the threshold voltage of the selected memory cell transistor MC corresponding to the S1 state is the voltage ΔVt larger than that of rise of the threshold voltage of the selected memory cell transistor MC corresponding to the S0 state. As shown in FIG. 19, sense amplifier 19 applies voltage VBL to the bit lines BL_B, BL_C, and BL_D. The selected memory cell transistors MC corresponding to groups B, C, and D are inhibited from being programmed.

The sense amplifier 19 applies the voltage ΔVt to the bit line BL_B corresponding to the S2 state of group B during the period of application of the pulse voltage Vp_B to the selected word line WL. The sense amplifier 19 also applies the voltage VSS to the bit line BL_B corresponding to the S3 state of group B. In the NAND string NS corresponding to group B, the selection transistor ST1 is turned on. Thus, the threshold voltage of the selected memory cell transistor MC corresponding to the S2 state of group B rises in accordance with a voltage difference between the voltage Vp_B and the voltage ΔVt. The threshold voltage of the selected memory cell transistor MC corresponding to the S3 state of group B rises in accordance with a voltage difference between the voltage Vp_B and the voltage VSS. As shown in FIG. 20, the amount of rise of the threshold voltage of the selected memory cell transistor MC corresponding to the S3 state is the voltage ΔVt larger than that of rise of the threshold voltage of the selected memory cell transistor MC corresponding to the S2 state. As shown in FIG. 19, the sense amplifier 19 applies the voltage VBL to the bit lines BL_A, BL_C, and BL_D. The selected memory cell transistors MC corresponding to groups A, C, and D are inhibited from being programmed.

During the period of application of the pulse voltage Vp_C to the selected word line WL, the sense amplifier 19 applies the voltage ΔVt to the bit line BL_C corresponding to the S4 state of group C. The sense amplifier 19 also applies the voltage VSS to the bit line BL_C corresponding to the S5 state of group C. In the NAND string NS corresponding to group C, the selection transistor ST1 is turned on. Thus, the threshold voltage of the selected memory cell transistor MC corresponding to the S4 state of group C rises in accordance with a voltage difference between the voltage Vp_C and the voltage ΔVt. The threshold voltage of the selected memory cell transistor MC corresponding to the S5 state of group C rises in accordance with a voltage difference between the voltage Vp_C and the voltage VSS. As shown in FIG. 20, the amount of rise of the threshold voltage of the selected memory cell transistor MC corresponding to the S5 state is the voltage ΔVt larger than that of rise of the threshold voltage of the selected memory cell transistor MC corresponding to the S4 state. As shown in FIG. 19, the sense amplifier 19 applies voltage VBL to the bit lines BL_A, BL_B, and BL_D. The selected memory cell transistors MC corresponding to groups A, B, and D are inhibited from being programmed.

During the period of application of the pulse voltage Vp_D to the selected word line WL, the sense amplifier 19 applies the voltage ΔVt to the bit line BL_D corresponding to the S6 state of group D. The sense amplifier 19 also applies the voltage VSS to the bit line BL_D corresponding to the S7 state of group D. In the NAND string NS corresponding to group D, the selection transistor ST1 is turned on. Thus, the threshold voltage of the selected memory cell transistor MC corresponding to the S6 state of group D rises in accordance with a voltage difference between the voltage Vp_D and the voltage ΔVt. The threshold voltage of the selected memory cell transistor MC corresponding to the S7 state of group D rises in accordance with a voltage difference between the voltage Vp_D and the voltage VSS. As shown in FIG. 20, the amount of rise of the threshold voltage of the selected memory cell transistor MC corresponding to the S7 state is the voltage ΔVt larger than that of rise of the threshold voltage of the selected memory cell transistor MC corresponding to the S6 state. As shown in FIG. 19, the sense amplifier 19 applies voltage VBL to the bit lines BL_A, BL_B, and BL_C. The selected memory cell transistors MC corresponding to groups A, B, and C are inhibited from being programmed.

During the period of time t1 to t2, the program verify operation PV is performed in the same manner as described with reference to FIG. 12.

During the period of time t2 to t3, a second program operation PG2 is performed. During the period of application of the pulse voltage Vp_A+ΔVp to the selected word line WL, the sense amplifier 19 applies the voltage ΔVt to the bit line BL_A corresponding to the selected memory cell transistor MC to be programmed in the S0 state, applies the voltage VSS to the bit line BL_A corresponding to the selected memory cell transistor MC to be programmed in the S1 state, and applies the voltage VBL to the bit line BL_A corresponding to the selected memory cell transistor MC that is inhibited from being programmed. As shown in FIG. 20, the width of the threshold voltage distribution in the S0 and S1 states becomes smaller than after the first program operation PG1. As shown in FIG. 19, the sense amplifier 19 applies the voltage VBL to the bit lines BL_B, BL_C, and BL_D.

During the period of application of the pulse voltage Vp_B+ΔVp to the selected word line WL, the sense amplifier 19 applies the voltage ΔVt to the bit line BL_B corresponding to the selected memory cell transistor MC to be programmed in the S2 state, applies the voltage VSS to the bit line BL_B corresponding to the selected memory cell transistor MC to be programmed in the S3 state, and applies the voltage VBL to the bit line BL_B corresponding to the selected memory cell transistor MC that is inhibited from being programmed. As shown in FIG. 20, the width of the threshold voltage distribution in the S2 and S3 states becomes smaller than after the first program operation PG1. As shown in FIG. 19, the sense amplifier 19 applies the voltage VBL to the bit lines BL_A, BL_C, and BL_D.

During the period of application of the pulse voltage Vp_C+ΔVp to the selected word line WL, the sense amplifier 19 applies the voltage ΔVt to the bit line BL_C corresponding to the selected memory cell transistor MC to be programmed in the S4 state, applies the voltage VSS to the bit line BL_C corresponding to the selected memory cell transistor MC to be programmed in the S5 state, and applies the voltage VBL to the bit line BL_C corresponding to the selected memory cell transistor MC that is inhibited from being programmed. As shown in FIG. 20, the width of the threshold voltage distribution in the S4 and S5 states becomes smaller than after the first program operation PG1. As shown in FIG. 19, the sense amplifier 19 applies the voltage VBL to the bit lines BL_A, BL_B, and BL_D.

During the period of application of the pulse voltage Vp_D+ΔVp to the selected word line WL, the sense amplifier 19 applies the voltage ΔVt to the bit line BL_D corresponding to the selected memory cell transistor MC to be programmed in the S6 state, applies the voltage VSS to the bit line BL_D corresponding to the selected memory cell transistor MC to be programmed in the S7 state, and applies the voltage VBL to the bit line BL_D corresponding to the selected memory cell transistor MC that is inhibited from being programmed. As shown in FIG. 20, the width of the threshold voltage distribution in the S6 and S7 states becomes smaller than after the first program operation PG1. As shown in FIG. 19, the sense amplifier 19 applies the voltage VBL to the bit lines BL_A, BL_B, and BL_C.

Like during the period of time t1 to t2, during the period of time t3 to t4, the program verify operation PV is performed.

During the period of time t4 to t5, a third program operation PG3 is performed. The sense amplifier 19 applies the voltage to each bit line BL in the same manner as the second program operation PG2. As shown in FIG. 20, the width of the threshold voltage distribution in the S0 to S7 states becomes smaller than after the second program operation PG2.

Like during the period of time t1 to t2, during the period of time t5 to t6, the program verify operation PV is performed as shown in FIG. 19. If the verify has passed, the multi-pulse write operation is terminated.

### 3.3 Advantageous Effect of Third Embodiment

The configuration of the semiconductor memory device 1 according to the third embodiment can bring about the same advantageous effect as that in the first embodiment.

In addition, the configuration of the semiconductor memory device 1 makes it possible to apply different voltages to the bit lines BL corresponding to a plurality of states included in the same group. More specifically, the semiconductor memory device 1 makes it possible to make the voltage of a bit line BL corresponding to a state with a lower threshold voltage distribution higher than the voltage of a bit line BL corresponding to a state with a higher threshold voltage distribution. Thus, the amount of rise of the threshold voltage of the memory cell transistor MC included in the state with a lower threshold voltage distribution can be made smaller than that of rise of the threshold voltage of the memory cell transistor MC included in the state with a higher threshold voltage distribution. Accordingly, adjacent states can be written at the same pulse voltage. The number of pulses in the multi-pulse writing operation can be reduced. Therefore, the semiconductor memory device 1 can improve in its processing capacity.

Note that in the third embodiment, one group includes two states, but one group may include three or more states. The third embodiment is combined with the first embodiment, that is, in the first embodiment, different voltages are applied to the bit lines BL corresponding to different states of the same group; however, the third embodiment may be combined with the second embodiment.

### 4. Modification, Etc.

According to above embodiments, a semiconductor memory device includes a plurality of memory strings (NS) stacked apart from each other in a first direction (Z direction) and each including a plurality of memory cells (MC) which are arranged side by side in a second direction (Y direction) intersecting the first direction and whose current paths are coupled in series, a word line (WL) extending in the first direction and coupled to gates of a plurality of first memory cells (MC) which are among the plurality of memory cells and stacked apart from each other in the first direction, a plurality of bit lines (BL) respectively coupled to the plurality of memory strings, a row decoder (18) coupled to the word line, a sense amplifier (19) coupled to the plurality of bit lines, and a controller (14) configured to perform a write operation by repeating a program loop including a program operation (PG) and a program verify (PV) operation. Each of the plurality of memory cells is capable of storing data corresponding to one of a plurality of states (S0 to S7). In the program operation of the plurality of first memory cells, the plurality of states are classified into a plurality of groups (A to D groups), and the row decoder applies to the word line a plurality of pulse voltages (Vp_A to Vp_D) respectively corresponding to the plurality of groups. In the program verify operation of the plurality of first memory cells, the row decoder applies to the word line a plurality of verify voltages (V0 to V7) respectively corresponding to the plurality of states.

With the configuration according to each of the foregoing embodiments, the semiconductor memory device can be improved in its processing capacity.

In addition to the foregoing embodiments, various modifications can be applied.

The “coupled” in the foregoing embodiments includes indirect coupling of elements between which a transistor, a resistor or something else intervenes.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a plurality of memory strings stacked apart from each other in a first direction and each including a plurality of memory cells which are arranged side by side in a second direction intersecting the first direction and whose current paths are coupled in series;
a word line extending in the first direction and coupled to gates of a plurality of first memory cells which are among the plurality of memory cells and stacked apart from each other in the first direction;
a plurality of bit lines respectively coupled to the plurality of memory strings;
a row decoder coupled to the word line;
a sense amplifier coupled to the plurality of bit lines; and
a controller configured to perform a write operation by repeating a program loop including a program operation and a program verify operation, wherein each of the plurality of memory cells is capable of storing data corresponding to one of a plurality of states,
in the program operation of the plurality of first memory cells, the plurality of states are classified into a plurality of groups, and the row decoder applies to the word line a plurality of pulse voltages respectively corresponding to the plurality of groups, and
in the program verify operation of the plurality of first memory cells, the row decoder applies to the word line a plurality of verify voltages respectively corresponding to the plurality of states.

2. The semiconductor memory device according to claim 1, wherein
each of the plurality of groups includes one or more of the plurality of states having adjacent threshold voltage distributions, and
each of the plurality of states is included in one of the plurality of groups.

3. The semiconductor memory device according to claim 2, wherein in the program operation, the row decoder continuously applies to the word line the plurality of pulse voltages respectively corresponding to the plurality of groups.

4. The semiconductor memory device according to claim 1, wherein
the plurality of states include a first state and a second state,
the plurality of groups include a first group including the first state and a second group including the second state,
the plurality of first memory cells include a second memory cell and a third memory cell which write data corresponding to the first state, and a fourth memory cell which writes data corresponding to the second state, and
in the program operation of the plurality of first memory cells, in a case where the second memory cell and the fourth memory cell are to be programmed and the third memory cell completes being programmed, a threshold voltage of the second memory cell rises during a first period of application of a first pulse voltage of the plurality of pulse voltages corresponding to the first group to the word line, and a threshold voltage of the fourth memory cell rises during a second period of application of a second pulse voltage of the plurality of pulse voltages corresponding to the second group to the word line.

5. The semiconductor memory device according to claim 4, wherein
the plurality of bit lines include a first bit line coupled to the second memory cell, a second bit line coupled to the third memory cell, and a third bit line coupled to the fourth memory cell, and
the sense amplifier applies a first voltage to the first bit line during the first period, and applies a second voltage that is higher than the first voltage to the second bit line and the third bit line.

6. The semiconductor memory device according to claim 1, wherein as a result of the program verify operation of a first program loop, the controller reassigns the plurality of groups in the program operation of a second program loop.

7. The semiconductor memory device according to claim 1, wherein
in a first program loop, the controller performs, after the program operation, the program verify operation for the word line using a potential obtained by varying, by a factor of more than one, a difference between a pulse voltage used in the program operation of the first program loop and a pulse voltage scheduled to be used in the program operation of a second program loop, and
in the program operation of the second program loop, the controller changes a configuration of the plurality of groups such that a plurality of second memory cells among the plurality of first memory cells are included in a same group, the second memory cells being subject to a same pulse voltage condition for a threshold voltage increase.

8. The semiconductor memory device according to claim 1, wherein
in a first program loop, the controller performs, after the program operation, the program verify operation for the word line using a potential obtained by varying, by a factor of more than one, a difference between a pulse voltage used in the program operation of the first program loop and a pulse voltage scheduled to be used in the program operation of a second program loop, and
in the program operation of the second program loop, the controller changes a configuration of the plurality of groups such that a second memory cell and a third memory cell among the plurality of first memory cells are included in different groups, the second memory cell and the third memory cell being subject to different pulse voltage conditions for a threshold voltage increase.

9. The semiconductor memory device according to claim 6, wherein a difference between a pulse voltage used in the program operation of the first program loop and a pulse voltage used in the program operation of the second program loop is equal to a difference in threshold voltage between two of the plurality of states having adjacent threshold voltage distributions.

10. The semiconductor memory device according to claim 7, wherein a difference between a pulse voltage used in the program operation of the first program loop and a pulse voltage used in the program operation of the second program loop is equal to a difference in threshold voltage between two of the plurality of states having adjacent threshold voltage distributions.

11. The semiconductor memory device according to claim 8, wherein a difference between a pulse voltage used in the program operation of the first program loop and a pulse voltage used in the program operation of the second program loop is equal to a difference in threshold voltage between two of the plurality of states having adjacent threshold voltage distributions.

12. The semiconductor memory device according to claim 1, wherein
the plurality of states include a first state, a second state whose threshold voltage is higher than a threshold voltage of the first state, and a third state whose threshold voltage is higher than the threshold voltage of the second state,
the plurality of groups include a first group including the first state and the second state, and a second group including the third state,
the plurality of first memory cells include a second memory cell and a third memory cell which write data corresponding to the first state, a fourth memory cell and a fifth memory cell which write data corresponding to the second state, and a sixth memory cell which writes data corresponding to the third state,
the plurality of bit lines include a first bit line coupled to the second memory cell, a second bit line coupled to the third memory cell, a third bit line coupled to the fourth memory cell, a fourth bit line coupled to the fifth memory cell, and a fifth bit line coupled to the sixth memory cell, and
in the program operation of the plurality of first memory cells, in a case where the second memory cell, the fourth memory cell, and the sixth memory cell are to be programmed and the third memory cell and the fifth memory cell complete being programmed, the sense amplifier applies a third voltage to the first bit line, applies a first voltage that is lower than the third voltage to the third bit line, and applies a second voltage that is higher than the third voltage to the fourth bit line and the fifth bit line during a first period of application of a first pulse voltage of the plurality of pulse voltages corresponding to the first group to the word line.

13. The semiconductor memory device according to claim 12, wherein the third voltage is equal to a difference between a threshold voltage of the first state and a threshold voltage of the second state.

14. The semiconductor memory device according to claim 12, wherein during the first period, the second memory cell and the fourth memory cell are to be programmed and the third memory cell, the fifth memory cell, and the sixth memory cell are inhibited from being programmed.

15. The semiconductor memory device according to claim 1, wherein each of the plurality of pulse voltages is stepped up each time the program loop is repeated.

16. The semiconductor memory device according to claim 15, wherein the plurality of pulse voltages have a same step-up width.

17. The semiconductor memory device according to claim 1, wherein the number of the plurality of groups is smaller than the number of the plurality of states.
